(19) United States
(12) Patent Application Publication
(10) Pub. No.: US 2026/0015709 A1
(43) Pub. Date: Jan. 15, 2026

(54) DEPOSITION MASK AND METHOD FOR MANUFACTURING THE SAME

(71) Applicant: Samsung Display Co., Ltd., Yongin-si (KR)

(72) Inventors: Su Bin BAE, Yongin-si (KR); Sung Won CHO, Yongin-si (KR)

(21) Appl. No.: 19/236,798

(22) Filed: Jun. 12, 2025

(30) Foreign Application Priority Data
Jul. 10, 2024 (KR) 10-2024-0091240

(51) Int. Cl. C23C 14/04; H10K 59/12; H10K 71/16

(52) U.S. Cl. CPC C23C 14/042; H10K 59/1201; H10K 71/166

(57) ABSTRACT

A deposition mask and a method for manufacturing the same are provided. A deposition mask includes: a mask substrate including a semiconductor wafer, a first coating film on the mask substrate, and a second coating film on the first coating film and including a hole pattern and a mask pattern that are alternately arranged, wherein an upper width of the hole pattern is less than a lower width thereof.

### CROSS-REFERENCE TO RELATED APPLICATION

The present application claims priority to and the benefit of Korean Patent Application No. 10-2024-0091240, filed on Jul. 10, 2024, in the Korean Intellectual Property Office, the entire disclosure of which is incorporated by reference herein.

### BACKGROUND

### 1. Field

The present disclosure relates to a deposition mask and a method for manufacturing the same.

### 2. Description of the Related Art

With the advance of information-oriented society, more and more demands are placed on display devices for displaying images in various ways. The display device may be a liquid crystal display, a field emission display, and/or a light emitting display. The light emitting display may include an organic light emitting display device including an organic light emitting diode (OLED) as a light emitting element or an inorganic light emitting display device including an inorganic light emitting diode as a light emitting element.

Recently, there is an increasing need for a display device that provides high-resolution images, for example, images with a resolution of 3000 PPI (Pixels Per Inch) or higher. To this end, an organic light emitting diode on silicon (OLEDoS), which is a high-resolution small organic light emitting display device, is used. The OLEDOS is an image display device in which an organic light emitting diode (OLED) is disposed on a semiconductor wafer substrate including complementary metal oxide semiconductor (CMOS).

In order to manufacture a self-luminous display device such as an organic light emitting display device, a deposition method is mainly used as a technology for depositing an organic material for each pixel, in which a thin film mask is firmly attached to a substrate to deposit the organic material at a required position. When depositing the organic material in a large-area organic light emitting display device, a fine metal mask (FMM), which is a thin-film metal mask, is widely used. However, this metal mask is not suitable for high-resolution patterning.

In this regard, in order to manufacture a high-resolution precise thin film mask, a fine silicon mask (FSM) manufactured using a semiconductor substrate such as a wafer is attracting attention.

### SUMMARY

Aspects and features of embodiments of the present disclosure provide a deposition mask for manufacturing a high-resolution display device, and a method for manufacturing the same.

Aspects and features of embodiments of the present disclosure also provide a deposition mask capable of improving the efficiency of a deposition process, and a method for manufacturing the same.

Aspects and features of embodiments of the present disclosure further provide a deposition mask capable of reducing or minimizing an imperfect deposition area, and a method for manufacturing the same.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to one or more embodiments of the present disclosure, there is provided a deposition mask including: a mask substrate including a semiconductor wafer, a first coating film on the mask substrate, and a second coating film on the first coating film and including a hole pattern and a mask pattern that are alternately arranged, wherein an upper width of the hole pattern is less than a lower width thereof.

In one or more embodiments, the first coating film includes silicon oxide.

In one or more embodiments, the second coating film includes silicon nitride.

In one or more embodiments, the second coating film includes low stress nitride.

In one or more embodiments, the deposition mask may further include a mask opening penetrating at least a part of the mask substrate and at least a part of the first coating film, wherein the mask opening communicates with the hole pattern.

In one or more embodiments, the mask substrate includes a first surface and a second surface located opposite the first surface, the first coating film includes a first upper coating film on the first surface, and a first lower coating film on the second surface, the second coating film includes a second upper coating film on the first surface, and a second lower coating film on the second surface, and the mask opening penetrates the second lower coating film, the first lower coating film, the mask substrate, and the first upper coating film.

In one or more embodiments, the mask pattern includes a first portion and a second portion on the first portion, and an upper width of the first portion is greater than a lower width of the first portion.

In one or more embodiments, a first angle between a bottom surface and a side surface of the first portion is different from a second angle between a bottom surface and a side surface of the second portion.

In one or more embodiments, the first angle is greater than the second angle.

In one or more embodiments, an angle between a bottom surface and a side surface of the first portion is an obtuse angle.

In one or more embodiments, the side surface of the first portion is an inclined surface that is inclined in an inward direction of the first portion as it goes from a top surface to a bottom surface thereof.

In one or more embodiments, an upper width of the second portion is greater than or equal to a lower width thereof.

In one or more embodiments, an angle between a bottom surface and a side surface of the second portion is a right angle or an obtuse angle.

In one or more embodiments, the side surface of the second portion is an inclined surface that is inclined in an inward direction of the second portion as it goes from a top surface to a bottom surface thereof.

In one or more embodiments, the first portion includes a first sub-portion and a second sub-portion on the first sub-portion, and a third angle between a bottom surface and a side surface of the first sub-portion is different from a fourth angle between a bottom surface and a side surface of the second sub-portion.

In one or more embodiments, the deposition mask may further include an alignment mark on the mask substrate, wherein the alignment mark is between the mask substrate and the first coating film or between the first coating film and the second coating film.

In one or more embodiments, the deposition mask may further include a third coating film on the second coating film, wherein the third coating film includes silicon oxide.

According to one or more embodiments of the present disclosure, there is provided a method for manufacturing a deposition mask, the method including: forming a first coating film on a mask substrate composed of a semiconductor wafer, and a second coating film on the first coating film, forming a mask pattern and a hole pattern in the second coating film, and forming a mask opening penetrating the mask substrate and the first coating film, wherein the forming of the mask pattern and the hole pattern in the second coating film includes, partially etching the second coating film to form a first groove, forming a passivation film on a side surface of the first groove, and mainly etching the remaining second coating film under the first groove to form the hole pattern and the mask pattern.

In one or more embodiments, the second coating film includes low stress nitride, and the second coating film is formed by a low pressure chemical vapor deposition (LPCVD) process.

In one or more embodiments, the passivation film includes a fluorocarbon-based polymer.

In an embodiment, the partially etching and the mainly etching of the second coating film are each performed by dry etching, and plasma is generated using an inductively coupled plasma method.

In one or more embodiments, a pressure within a chamber in the partially etching is lower than a pressure within the chamber in the mainly etching.

In one or more embodiments, a source power in the partially etching is lower than a source power in the mainly etching.

In one or more embodiments, a bias power in the partially etching is lower than a bias power in the mainly etching.

According to one or more embodiments of the present disclosure, there is provided a an electronic device including, a processor to provide input image data, and a display device to display an image based on the input image data, wherein the display device is manufactured using the deposition mask of claim 1.

The deposition mask and the method for manufacturing the same according to one or more embodiments of the present disclosure, it is possible to manufacture a high-resolution display device.

The deposition mask and the method for manufacturing the same according to one or more embodiments of the present disclosure, it is possible to improve the efficiency of a deposition process.

The deposition mask and the method for manufacturing the same according to one or more embodiments of the present disclosure, it is possible to reduce or minimize an imperfect deposition area.

However, effects according to the embodiments of the present disclosure are not limited to those exemplified above and various other effects are incorporated herein.

### BRIEF DESCRIPTION OF THE DRAWINGS

The above and other aspects and features of the present disclosure will become more apparent by describing in detail embodiments thereof with reference to the attached drawings, in which:

FIG. 1 is an exploded perspective view showing a display device according to one or more embodiments;

FIG. 2 is a block diagram illustrating a display device according to one or more embodiments;

FIG. 3 is an equivalent circuit diagram of a first sub-pixel according to one or more embodiments;

FIG. 4 is a plan view illustrating an example of a display panel according to one or more embodiments;

FIGS. 5 and 6 are plan views illustrating embodiments of the display area of FIG. 4;

FIG. 7 is a cross-sectional view illustrating an example of a display panel taken along the line X1-X1′ of FIG. 5;

FIG. 8 is a cross-sectional view showing another example of a display panel included in a display device according to one or more embodiments;

FIG. 9 is an exploded perspective view illustrating a head mounted display according to one or more embodiments;

FIG. 10 is a perspective view showing an augmented reality content providing device according to one or more embodiments;

FIG. 11 is a rear exploded perspective view of the augmented reality content providing device of FIG. 10;

FIG. 12 is a front exploded perspective view of the augmented reality content providing device of FIG. 10;

FIG. 13 is a plan view showing a mother semiconductor substrate including a display cell according to one or more embodiments;

FIG. 14 is a plan view showing a deposition mask according to one or more embodiments;

FIG. 15 is a cross-sectional view taken along the line X2-X2′ of FIG. 14;

FIG. 16 is an enlarged view of an area A of FIG. 15;

FIG. 17 is a cross-sectional view showing a process of manufacturing a display device using a deposition mask according to one or more embodiments;

FIG. 18 is a schematic diagram showing an emission area and a shadow area formed when manufacturing a display device using a deposition mask according to a comparative example;

FIG. 19 is a schematic diagram showing an emission area formed when manufacturing a display device using a deposition mask according to one or more embodiments;

FIG. 20 is a plan view showing a deposition mask according to one or more embodiments;

FIG. 21 is a cross-sectional view showing a deposition mask according to one or more embodiments;

FIG. 22 is a flowchart showing a method of manufacturing a deposition mask according to one or more embodiments;

FIG. 23 is a cross-sectional view showing the step S100 of FIG. 22;

FIG. 24 is a cross-sectional view showing the step S200 of FIG. 22;

FIG. 25 is a cross-sectional view showing the step S300 of FIG. 22;

FIG. 26 is a cross-sectional view showing the step S400 of FIG. 22;

FIG. 27 is a cross-sectional view showing the step S500 of FIG. 22;

FIG. 28 is a cross-sectional view showing the step S600 of FIG. 22;

FIG. 29 is a flowchart showing detailed sub-steps of the step S500 of FIG. 22;

FIG. 30 is a cross-sectional view showing the step S510 of FIG. 29;

FIG. 31 is a cross-sectional view showing the step S520 of FIG. 29; and

FIGS. 32 and 33 are cross-sectional views showing the step S530 of FIG. 29.

### DETAILED DESCRIPTION OF THE EMBODIMENTS

The present disclosure will now be described more fully hereinafter with reference to the accompanying drawings, in which embodiments of the present disclosure are shown. The present disclosure may, however, be embodied in different forms and should not be construed as limited to the embodiments set forth herein. Rather, these embodiments are provided so that the present disclosure will be thorough and complete, and will fully convey the scope of the present disclosure to those skilled in the art.

It will also be understood that when a layer is referred to as being “on” another layer or substrate, it can be directly on the other layer or substrate, or intervening layers may also be present. The same reference numbers indicate the same components throughout the specification.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art. The expression “not overlap” may include meaning such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

The spatially relative terms “below,” “beneath,” “lower,” “above,” “upper,” or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

When an element is referred to as being “connected” or “coupled” to another element, the element may be “directly connected” or “directly coupled” to another element, or “electrically connected” or “electrically coupled” to another element with one or more intervening elements interposed therebetween. It will be further understood that when the terms “comprises,” “comprising,” “has,” “have,” “having,” “includes” and/or “including” are used, they may specify the presence of stated features, integers, steps, operations, elements and/or components, but do not preclude the presence or addition of other features, integers, steps, operations, elements, components, and/or any combination thereof.

It will be understood that, although the terms “first,” “second,” “third,” or the like may be used herein to describe various elements, these elements should not be limited by these terms. These terms are used to distinguish one element from another element or for the convenience of description and explanation thereof. For example, when “a first element” is discussed in the description, it may be termed “a second element” or “a third element,” and “a second element” and “a third element” may be termed in a similar manner without departing from the teachings herein.

The terms “about” or “approximately” as used herein is inclusive of the stated value and means within an acceptable range of deviation for the particular value as determined by one of ordinary skill in the art, considering the measurement in question and the error associated with measurement of the particular quantity (for example, the limitations of the measurement system). For example, “about” may mean within one or more standard deviations, or within ±30%, 20%, 10%, 5% of the stated value.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.” In the specification and the claims, the phrase “at least one of” is intended to include the meaning of “at least one selected from the group of” for the purpose of its meaning and interpretation. For example, “at least one of A and B” may be understood to mean “A, B, or A and B.” Unless otherwise defined or implied, all terms used herein (including technical and scientific terms) have the same meaning as commonly understood by those skilled in the art to which this disclosure pertains. It will be further understood that terms, such as those defined in commonly used dictionaries, should be interpreted as having a meaning that is consistent with their meaning in the context of the relevant art and will not be interpreted in an ideal or excessively formal sense unless clearly defined in the specification.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

Hereinafter, embodiments of the present disclosure will be described in detail with reference to the accompanying drawings.

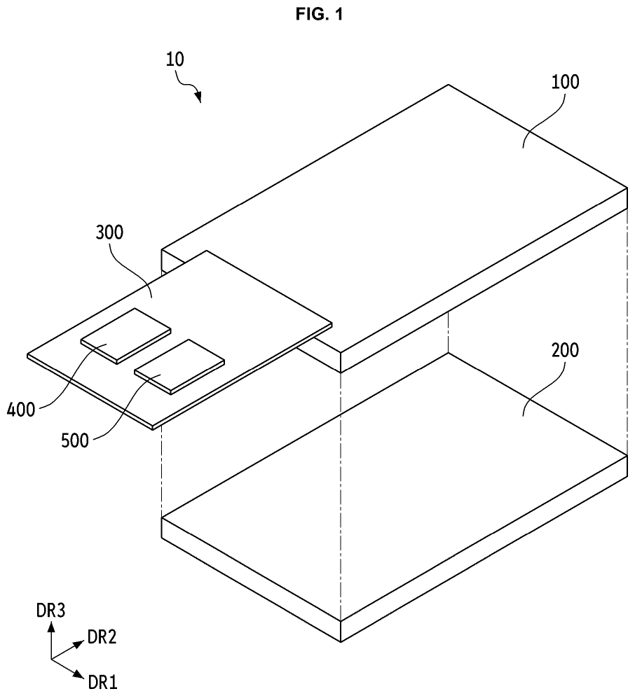

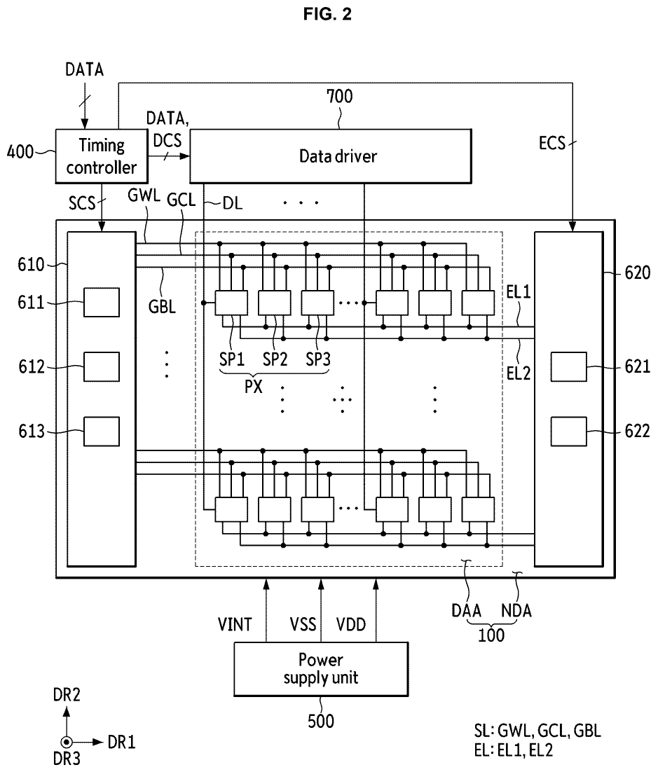

FIG. 1 is an exploded perspective view showing a display device according to one or more embodiments. FIG. 2 is a block diagram illustrating a display device according to one or more embodiments.

Referring to FIGS. 1 and 2, a display device 10 according to one or more embodiments may be a device displaying a moving image and/or a still image. The display device 10 according to one or more embodiments may be applied to portable electronic devices such as a mobile phone, a smartphone, a tablet personal computer, a mobile communication terminal, an electronic organizer, an electronic book, a portable multimedia player (PMP), a navigation system, an ultra mobile PC (UMPC), and/or the like. For example, the display device 10 according to one or more embodiments may be applied as a display unit of a television, a laptop, a monitor, a billboard, and/or an Internet-of-Things (IoT) terminal. Alternatively, the display device 10 according to one or more embodiments may be applied to a smart watch, a watch phone, a head mounted display (HMD) for implementing virtual reality and augmented reality, and/or the like.

The display device 10 according to one or more embodiments may include a display panel 100, a heat dissipation layer 200, a circuit board 300, a timing control circuit (e.g., a timing controller) 400, and a power supply circuit (e.g., a power supply unit) 500.

The display panel 100 may have a planar shape similar to a quadrilateral shape. For example, the display panel 100 may have a planar shape similar to a quadrilateral shape, having a short side of a first direction DR1 and a long side of a second direction DR2 intersecting the first direction DR1. In the display panel 100, a corner where a short side in the first direction DR1 and a long side in the second direction DR2 meet may be right-angled or rounded with a suitable curvature (e.g., a predetermined curvature). The planar shape of the display panel 100 is not limited to a quadrilateral shape, and may be a shape similar to another polygonal shape, a circular shape, or an elliptical shape. The planar shape of the display device 10 may conform to the planar shape of the display panel 100, but the present disclosure is not limited thereto.

In the illustrated figure, the first direction DR1 and the second direction DR2 cross each other as horizontal directions. For example, the first direction DR1 and the second direction DR2 may be orthogonal to each other. In addition, a third direction DR3 crosses the first direction DR1 and the second direction DR2, and may be, for example, perpendicular directions orthogonal to each other. Unless otherwise defined, in the present specification, directions indicated by arrows of the first to third directions DR1, DR2, and DR3 may be referred to as one side, and the opposite directions thereto may be referred to as the other side. Also, the terms “above,” “upper side,” “upper portion,” “top,” and “top surface,” as used herein, refer to a direction indicated by an arrow in the drawing in the third direction DR3 based on the drawings, and the terms “below,” “lower side,” “lower portion,” “bottom,” and “bottom surface,” as used herein, refer to a direction opposite to the direction indicated by the arrow in the third direction DR3 based on the drawings.

The display panel 100 may include a display area DAA displaying an image and a non-display area NDA not displaying an image as shown in FIG. 2.

The display area DAA may include a plurality of pixels PX, a plurality of scan lines SL, a plurality of emission control lines EL, and a plurality of data lines DL.

The plurality of pixels PX may be arranged in a matrix form along the first direction DR1 and the second direction DR2. For example, the plurality of pixels PX may be arranged along rows and columns of a matrix along the first direction DR1 and the second direction DR2. The plurality of scan lines SL and the plurality of emission control lines EL may extend in the first direction DR1, while being arranged along the second direction DR2. The plurality of data lines DL may extend in the second direction DR2, while being arranged along the first direction DR1.

The plurality of scan lines SL may include a plurality of write scan lines GWL, a plurality of control scan lines GCL, and a plurality of bias scan lines GBL. The plurality of emission control lines EL may include a plurality of first emission control lines EL1 and a plurality of second emission control lines EL2.

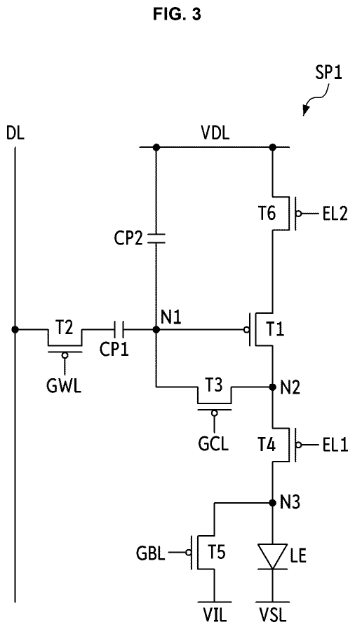

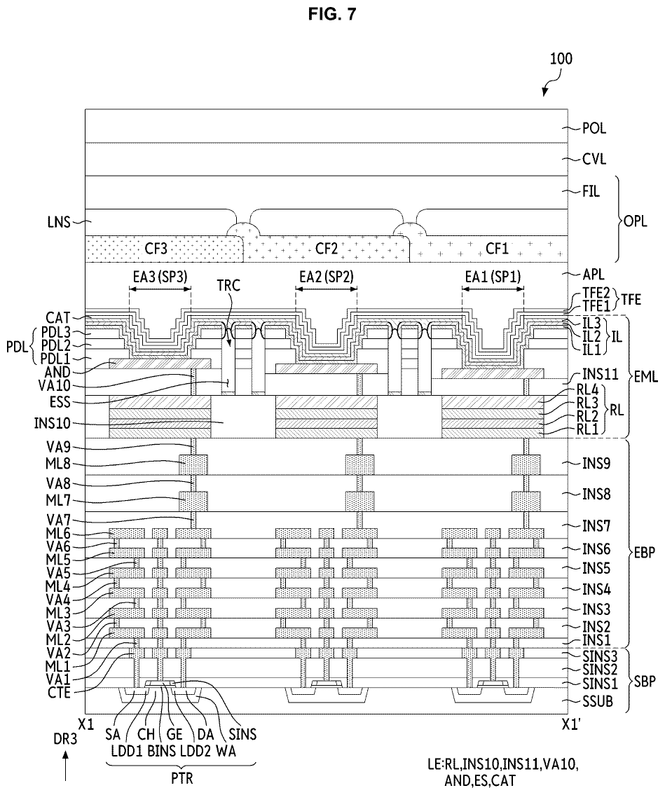

The plurality of pixels PX may include a plurality of sub-pixels SP1, SP2, and SP3. The plurality of sub-pixels SP1, SP2, and SP3 may include a plurality of pixel transistors as shown in FIG. 3 to be described later, and the plurality of pixel transistors may be formed by a semiconductor process and disposed on a semiconductor substrate SSUB (see FIG. 7). For example, the plurality of pixel transistors of a data driver 700 may be formed of complementary metal oxide semiconductor (CMOS). Each of the plurality of sub-pixels SP1, SP2, and SP3 may be connected to one write scan line GWL from among the plurality of write scan lines GWL, one control scan line GCL from among the plurality of control scan lines GCL, one bias scan line GBL from among the plurality of bias scan lines GBL, one first emission control line EL1 from among the plurality of first emission control lines EL1, one second emission control line EL2 from among the plurality of second emission control lines EL2, and one data line DL from among the plurality of data lines DL. Each of the plurality of sub-pixels SP1, SP2, and SP3 may receive a data voltage of the data line DL in response to a write scan signal of the write scan line GWL, and emit light from the light emitting element according to the data voltage.

The non-display area NDA may include a scan driver 610, an emission driver 620, and the data driver 700.

The scan driver 610 may include a plurality of scan transistors, and the emission driver 620 may include a plurality of light emitting transistors. The plurality of scan transistors and the plurality of light emitting transistors may be formed through a semiconductor process, and disposed on the semiconductor substrate SSUB (see FIG. 7). For example, the plurality of scan transistors and the plurality of light emitting transistors may be formed of CMOS. Although it is illustrated in FIG. 2 that the scan driver 610 is disposed on the left side of the display area DAA and the emission driver 620 is disposed on the right side of the display area DAA, the present disclosure is not limited thereto. For example, the scan driver 610 and the emission driver 620 may be disposed on both the left side and the right side of the display area DAA.

The scan driver 610 may include a write scan signal output unit 611, a control scan signal output unit 612, and a bias scan signal output unit 613. Each of the write scan signal output unit 611, the control scan signal output unit 612, and the bias scan signal output unit 613 may receive a scan timing control signal SCS from the timing control circuit 400. The write scan signal output unit 611 may generate write scan signals according to the scan timing control signal SCS of the timing control circuit 400 and output them sequentially to the write scan lines GWL. The control scan signal output unit 612 may generate control scan signals in response to the scan timing control signal SCS and sequentially output them to the control scan lines GCL. The bias scan signal output unit 613 may generate bias scan signals according to the scan timing control signal SCS and output them sequentially to bias scan lines EBL.

The emission driver 620 may include a first emission control driver 621 and a second emission control driver 622. Each of the first emission control driver 621 and the second emission control driver 622 may receive an emission timing control signal ECS from the timing control circuit 400. The first emission control driver 621 may generate first emission control signals according to the emission timing control signal ECS and sequentially output them to the first emission control lines EL1. The second emission control driver 622 may generate second emission control signals according to the emission timing control signal ECS and sequentially output them to the second emission control lines EL2.

The data driver 700 may include a plurality of data transistors, and the plurality of data transistors may be formed through a semiconductor process, and disposed on the semiconductor substrate SSUB (see FIG. 7). For example, the plurality of data transistors may be formed of CMOS.

The data driver 700 may receive digital video data DATA and a data timing control signal DCS from the timing control circuit 400. The data driver 700 may convert the digital video data DATA into analog data voltages according to the data timing control signal DCS and output the analog data voltages to the data lines DL. In this case, the sub-pixels SP1, SP2, and SP3 may be selected by the write scan signal of the scan driver 610, and data voltages may be supplied to the selected sub-pixels SP1, SP2, and SP3.

The heat dissipation layer 200 may overlap the display panel 100 in a third direction DR3, which is a thickness direction of the display panel 100. The heat dissipation layer 200 may be disposed on one surface of the display panel 100, for example, on the rear surface thereof. The heat dissipation layer 200 may serve to dissipate heat generated from the display panel 100. The heat dissipation layer 200 may include a metal layer having high thermal conductivity, such as graphite, silver (Ag), copper (Cu), and/or aluminum (Al).

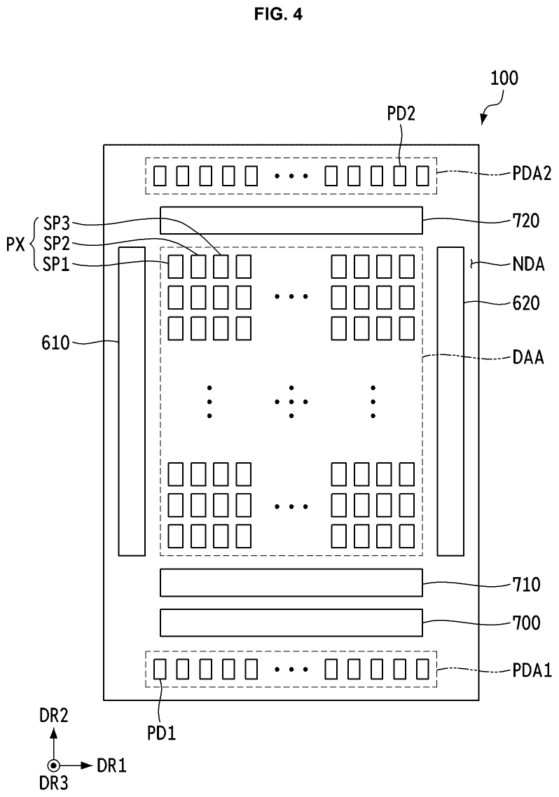

The circuit board 300 may be electrically connected to a plurality of first pads PD1 (see FIG. 4) of a first pad portion PDA1 (see FIG. 4) of the display panel 100 by using a conductive adhesive member such as an anisotropic conductive film. The circuit board 300 may be a flexible printed circuit board (FPCB) with a flexible material, or a flexible film. Although the circuit board 300 is illustrated in FIG. 1 as being unfolded, the circuit board 300 may be bent. In this case, one end of the circuit board 300 may be disposed on the rear surface of the display panel 100 and/or the rear surface of the heat dissipation layer 200. One end of the circuit board 300 may be an opposite end of the other end of the circuit board 300 connected to the plurality of first pads PD1 (see FIG. 4) of the first pad portion PDA1 (see FIG. 4) of the display panel 100 by using a conductive adhesive member.

The timing control circuit 400 may receive digital video data DATA and timing signals inputted from the outside. The timing control circuit 400 may generate the scan timing control signal SCS, the emission timing control signal ECS, and the data timing control signal DCS for controlling the display panel 100 in response to the timing signals. The timing control circuit 400 may output the scan timing control signal SCS to the scan driver 610, and output the emission timing control signal ECS to the emission driver 620. The timing control circuit 400 may output the digital video data DATA and the data timing control signal DCS to the data driver 700.

The power supply circuit 500 may generate a plurality of panel driving voltages according to a power voltage from the outside. For example, the power supply circuit 500 may generate a first driving voltage VSS, a second driving voltage VDD, and a third driving voltage VINT and supply them to the display panel 100. The first driving voltage VSS, the second driving voltage VDD, and the third driving voltage VINT will be described later in conjunction with FIG. 3.

Each of the timing control circuit 400 and the power supply circuit 500 may be formed as an integrated circuit (IC) and attached to one surface of the circuit board 300. In this case, the scan timing control signal SCS, the emission timing control signal ECS, the digital video data DATA, and the data timing control signal DCS of the timing control circuit 400 may be supplied to the display panel 100 through the circuit board 300. Further, the first driving voltage VSS, the second driving voltage VDD, and the third driving voltage VINT of the power supply circuit 500 may be supplied to the display panel 100 through the circuit board 300.

Alternatively, each of the timing control circuit 400 and the power supply circuit 500 may be disposed in the non-display area NDA of the display panel 100, similarly to the scan driver 610, the emission driver 620, and the data driver 700. In this case, the timing control circuit 400 may include a plurality of timing transistors, and each power supply circuit 500 may include a plurality of power transistors. The plurality of timing transistors and the plurality of power transistors may be formed through a semiconductor process, and disposed on the semiconductor substrate SSUB (see FIG. 7). For example, the plurality of timing transistors and the plurality of power transistors may be formed of CMOS. Each of the timing control circuit 400 and the power supply circuit 500 may be disposed between the data driver 700 and the first pad portion PDA1 (see FIG. 4).

FIG. 3 is an equivalent circuit diagram of a first sub-pixel according to one or more embodiments.

Referring to FIG. 3 in addition to FIGS. 1 and 2, the first sub-pixel SP1 may be connected to the write scan line GWL, the control scan line GCL, the bias scan line GBL, the first emission control line EL1, the second emission control line EL2, and the data line DL. Further, the first sub-pixel SP1 may be connected to a first driving voltage line VSL to which the first driving voltage VSS corresponding to a low potential voltage is applied, a second driving voltage line VDL to which the second driving voltage VDD corresponding to a high potential voltage is applied, and a third driving voltage line VIL to which the third driving voltage VINT corresponding to an initialization voltage is applied. That is, the first driving voltage line VSL may be a low potential voltage line, the second driving voltage line VDL may be a high potential voltage line, and the third driving voltage line VIL may be an initialization voltage line. In this case, the first driving voltage VSS may be lower than the third driving voltage VINT. The second driving voltage VDD may be higher than the third driving voltage VINT.

The first sub-pixel SP1 may include a plurality of transistors T1 to T6, a light emitting element LE, a first capacitor CP1, and a second capacitor CP2.

The light emitting element LE may emit light in response to a driving current (source-drain current) flowing through the channel of a first transistor T1. A light emission amount of the light emitting element LE may be proportional to the driving current. The light emitting element LE may be disposed between a fourth transistor T4 and the first driving voltage line VSL. The first electrode of the light emitting element LE may be connected to the drain electrode of the fourth transistor T4, and the second electrode thereof may be connected to the first driving voltage line VSL. The first electrode of the light emitting element LE may be an anode electrode, and the second electrode of the light emitting element LE may be a cathode electrode. The light emitting element LE may be an organic light emitting diode (OLED) including a first electrode, a second electrode, and an organic light emitting layer disposed between the first electrode and the second electrode, but the present disclosure is not limited thereto. For example, the light emitting element LE may be an inorganic light emitting element including a first electrode, a second electrode, and an inorganic semiconductor disposed between the first electrode and the second electrode, and the light emitting element LE may be, e.g., a micro light emitting diode.

The first transistor T1 may be a driving transistor that controls a driving current flowing between the source electrode and the drain electrode thereof according to a voltage applied to the gate electrode thereof. The first transistor T1 may include a gate electrode connected to a first node N1, a source electrode connected to the drain electrode of a sixth transistor T6, and a drain electrode connected to a second node N2.

A second transistor T2 may be disposed between one electrode of the first capacitor CP1 and the data line DL. The second transistor T2 may be turned on by the write scan signal of the write scan line GWL to connect the one electrode of the first capacitor CP1 to the data line DL. Accordingly, the data voltage of the data line DL may be applied to the one electrode of the first capacitor CP1. The second transistor T2 may include a gate electrode connected to the write scan line GWL, a source electrode connected to the data line DL, and a drain electrode connected to the one electrode of the first capacitor CP1.

A third transistor T3 may be disposed between the first node N1 and the second node N2. The third transistor T3 may be turned on by the control scan signal of the control scan line GCL to connect the first node N1 to the second node N2. For this reason, because the gate electrode and the source electrode of the first transistor T1 are connected, the first transistor T1 may operate like a diode (e.g., the first transistor T1 may be diode-connected). The third transistor T3 may include a gate electrode connected to the control scan line GCL, a source electrode connected to the second node N2, and a drain electrode connected to the first node N1.

The fourth transistor T4 may be connected between the second node N2 and a third node N3. The fourth transistor T4 may be turned on by the first emission control signal of the first emission control line EL1 to connect the second node N2 to the third node N3. Accordingly, the driving current of the first transistor T1 may be supplied to the light emitting element LE. The fourth transistor T4 may include a gate electrode connected to the first emission control line EL1, a source electrode connected to the second node N2, and a drain electrode connected to the third node N3.

A fifth transistor T5 may be disposed between the third node N3 and the third driving voltage line VIL. The fifth transistor T5 may be turned on by the bias scan signal of the bias scan line GBL to connect the third node N3 to the third driving voltage line VIL. Accordingly, the third driving voltage VINT of the third driving voltage line VIL may be applied to the first electrode of the light emitting element LE. The fifth transistor T5 may include a gate electrode connected to the bias scan line GBL, a source electrode connected to the third node N3, and a drain electrode connected to the third driving voltage line VIL.

The sixth transistor T6 may be disposed between the source electrode of the first transistor T1 and the second driving voltage line VDL. The sixth transistor T6 may be turned on by the second emission control signal of the second emission control line EL2 to connect the source electrode of the first transistor T1 to the second driving voltage line VDL. Accordingly, the second driving voltage VDD of the second driving voltage line VDL may be applied to the source electrode of the first transistor T1. The sixth transistor T6 may include a gate electrode connected to the second emission control line EL2, a source electrode connected to the second driving voltage line VDL, and a drain electrode connected to the source electrode of the first transistor T1.

The first capacitor CP1 may be disposed between the first node N1 and the drain electrode of the second transistor T2. The first capacitor CP1 may include one electrode connected to the drain electrode of the second transistor T2 and the other electrode connected to the first node N1.

The second capacitor CP2 may be disposed between the gate electrode of the first transistor T1 (or the first node N1) and the second driving voltage line VDL. The second capacitor CP2 may include one electrode connected to the gate electrode of the first transistor T1 (or the first node N1) and the other electrode connected to the second driving voltage line VDL.

The first node N1 may be a junction between the gate electrode of the first transistor T1, the drain electrode of the third transistor T3, the other electrode of the first capacitor CP1, and the one electrode of the second capacitor CP2. The second node N2 may be a junction between the drain electrode of the first transistor T1, the source electrode of the third transistor T3, and the source electrode of the fourth transistor T4. The third node N3 may be a junction between the drain electrode of the fourth transistor T4, the source electrode of the fifth transistor T5, and the first electrode of the light emitting element LE.

Each of the first to sixth transistors T1 to T6 may be a metal-oxide-semiconductor field effect transistor (MOSFET). For example, each of the first to sixth transistors T1 to T6 may be a P-type MOSFET, but the present disclosure is not limited thereto. Each of the first to sixth transistors T1 to T6 may be an N-type MOSFET. Alternatively, some of the first to sixth transistors T1 to T6 may be P-type MOSFETs, and each of the remaining transistors may be an N-type MOSFET.

Although it is illustrated in FIG. 3 that the first sub-pixel SP1 includes six transistors T1 to T6 and two capacitors CP1 and CP2, the equivalent circuit diagram of the first sub-pixel SP1 is not limited to that shown in FIG. 3. For example, the number of the transistors and the number of the capacitors of the first sub-pixel SP1 may be changed in various ways.

Further, the equivalent circuit diagram of the second sub-pixel SP2 and the equivalent circuit diagram of the third sub-pixel SP3 may be substantially the same as the equivalent circuit diagram of the first sub-pixel SP1 described in conjunction with FIG. 3. Therefore, the description of the equivalent circuit diagram of the second sub-pixel SP2 and the equivalent circuit diagram of the third sub-pixel SP3 is not repeated in the present disclosure.

FIG. 4 is a plan view illustrating an example of a display panel according to one or more embodiments.

Referring to FIG. 4, the display area DAA of the display panel 100 according to one or more embodiments may include the plurality of pixels PX arranged in a matrix form. The non-display area NDA of the display panel 100 according to one or more embodiments may include the scan driver 610, the emission driver 620, the data driver 700, a first distribution circuit 710, a second distribution circuit 720, the first pad portion PDA1, and a second pad portion PDA2.

The scan driver 610 may be disposed on the first side of the display area DAA, and the emission driver 620 may be disposed on the second side of the display area DAA. For example, the scan driver 610 may be disposed on the other side of the display area DAA in the first direction DR1, and the emission driver 620 may be disposed on one side of the display area DAA in the first direction DR1. That is, the scan driver 610 may be disposed on the left side of the display area DAA, and the emission driver 620 may be disposed on the right side of the display area DAA. However, the present disclosure is not limited thereto, and the scan driver 610 and the emission driver 620 may be disposed on both the first side and the second side of the display area DAA.

The first pad portion PDA1 may include the plurality of first pads PD1 connected to pads or bumps of the circuit board 300 through a conductive adhesive member. The first pad portion PDA1 may be disposed on the third side of the display area DAA. For example, the first pad portion PDA1 may be disposed on the other side of the display area DAA in the second direction DR2. That is, the first pad portion PDA1 may be disposed on the lower side of the display area DAA.

The first pad portion PDA1 may be disposed outside the data driver 700 in the second direction DR2. That is, the first pad portion PDA1 may be disposed closer to the edge of the display panel 100 than the data driver 700 is.

The second pad portion PDA2 may include a plurality of second pads PD2 corresponding to inspection pads that test whether the display panel 100 operates normally. The plurality of second pads PD2 may be connected to a jig or a probe pin during an inspection process, or may be connected to a circuit board for inspection. The circuit board for inspection may be a printed circuit board (PCB) made of a rigid material or a flexible printed circuit board (FPCB) made of a flexible material.

The first distribution circuit 710 may distribute data voltages applied through the first pad portion PDA1 to the plurality of data lines DL. For example, the first distribution circuit 710 may distribute the data voltages applied through one first pad PD1 of the first pad portion PDA1 to the P (P is a positive integer of 2 or more) data lines DL, and as a result, the number of the plurality of first pads PD1 may be reduced. The first distribution circuit 710 may be disposed on the third side of the display area DAA of the display panel 100. For example, the first distribution circuit 710 may be disposed on the other side of the display area DAA in the second direction DR2. That is, the first distribution circuit 710 may be disposed on the lower side of the display area DAA.

The second distribution circuit 720 may distribute signals applied through the second pad portion PDA2 to the scan driver 610, the emission driver 620, and the data lines DL. The second pad portion PDA2 and the second distribution circuit 720 may be configured to inspect the operation of each of the pixels PX in the display area DAA. The second distribution circuit 720 may be disposed on the fourth side of the display area DAA of the display panel 100. For example, the second distribution circuit 720 may be disposed on one side of the display area DAA in the second direction DR2. That is, the second distribution circuit 720 may be disposed on the upper side of the display area DAA.

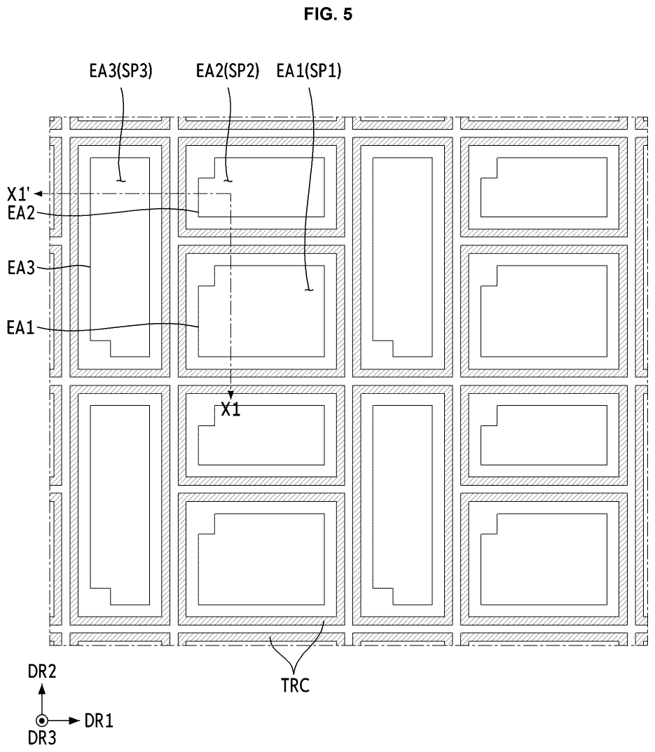

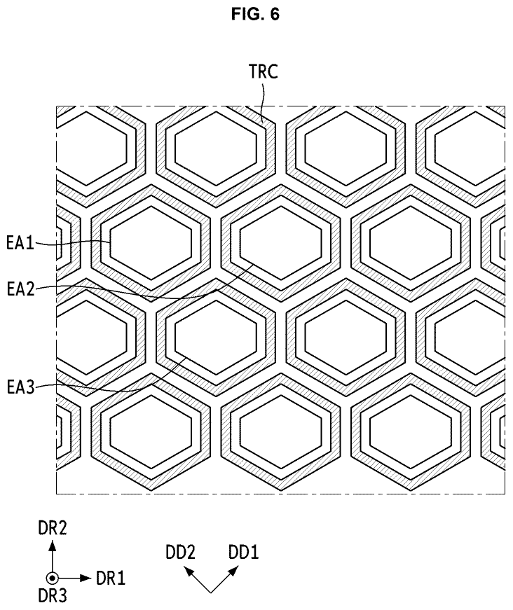

FIGS. 5 and 6 are plan views illustrating embodiments of the display area of FIG. 4.

Referring to FIGS. 5 and 6, each of the pixels PX may include the first emission area EA1 that is an emission area of the first sub-pixel SP1, the second emission area EA2 that is an emission area of the second sub-pixel SP2, and the third emission area EA3 that is an emission area of the third sub-pixel SP3.

In one or more embodiments, as shown in FIGS. 5 and 6, the first emission area EA1, the second emission area EA2, and the third emission area EA3 may have, in a plan view, a hexagonal shape formed of six straight lines, but the present disclosure is not limited thereto. The first emission area EA1, the second emission area EA2, and the third emission area EA3 may have a polygonal shape other than a hexagon, a circular shape, an elliptical shape, or an atypical shape in a plan view.

In one or more embodiments, as shown in FIG. 5, the maximum length of the third emission area EA3 in the first direction DR1 may be less than the maximum length of the first emission area EA1 in the first direction DR1 and the maximum length of the second emission area EA2 in the first direction DR1. The maximum length of the first emission area EA1 in the first direction DR1 and the maximum length of the second emission area EA2 in the first direction DR1 may be substantially the same.

In one or more embodiments, as shown in FIG. 5, the maximum length of the third emission area EA3 in the second direction DR2 may be greater than the maximum length of the first emission area EA1 in the second direction DR2 and the maximum length of the second emission area EA2 in the second direction DR2. The maximum length of the first emission area EA1 in the second direction DR2 may be greater than the maximum length of the second emission area EA2 in the second direction DR2.

In one or more embodiments, as shown in FIG. 5, the first emission area EA1 and the second emission area EA2 in each of the plurality of pixels PX may be adjacent to each other in the second direction DR2. The first emission area EA1 and the third emission area EA3 may be adjacent to each other in the first direction DR1. The second emission area EA2 and the third emission area EA3 may be adjacent to each other in the first direction DR1. The area of the first emission area EA1, the area of the second emission area EA2, and the area of the third emission area EA3 may be different.

In one or more embodiments, as shown in FIG. 6, in each of the plurality of pixels PX, the first emission area EA1 and the second emission area EA2 may be adjacent to each other in the first direction DR1, but the second emission area EA2 and the third emission area EA3 may be adjacent to each other in a first diagonal direction DD1, and the first emission area EA1 and the third emission area EA3 may be adjacent to each other in a second diagonal direction DD2.

In the illustrated drawing, the first diagonal direction DD1 intersects each of the first direction DR1 and the second direction DR2 as horizontal directions. For example, the first diagonal direction DD1 may be a direction inclined by 45 degrees with respect to the first direction DR1 and the second direction DR2, but the present disclosure is not limited thereto. The second diagonal direction DD2 intersects each of the first direction DR1 and the second direction DR2 as horizontal directions. For example, the second diagonal direction DD1 may be a direction inclined by 45 degrees with respect to the opposite direction of the first direction DR1 and the second direction DR2, but the present disclosure is not limited thereto. The second diagonal direction DD2 may be a direction that is perpendicular to the first diagonal direction DD1.

The first emission area EA1 may emit light of a first color, the second emission area EA2 may emit light of a second color, and the third emission area EA3 may emit light of a third color. Here, the light of the first color may be light of a red wavelength band, the light of the second color may be light of a green wavelength band, and the light of the third color may be light of a blue wavelength band. For example, the blue wavelength band may be a wavelength band of light whose main peak wavelength is in the range of approximately 370 nm to 460 nm, the green wavelength band may be a wavelength band of light whose main peak wavelength is in the range of approximately 480 nm to 560 nm, and the red wavelength band may be a wavelength band of light whose main peak wavelength is in the range of approximately 600 nm to 750 nm.

It is exemplified in FIGS. 5 and 6 that each of the plurality of pixels PX includes three emission areas EA1, EA2, and EA3, but the present disclosure is not limited thereto. That is, each of the plurality of pixels PX may include four or more emission areas.

In addition, the shape and arrangement of the emission areas of the plurality of pixels PX are not limited to those illustrated in FIGS. 5 and 6. For example, the emission areas of the plurality of pixels PX may be disposed in a stripe structure in which the emission areas are arranged along the first direction DR1, a PENTILE® structure in which the emission areas are arranged in a diamond shape, or a hexagonal structure in which the emission areas having, in a plan view, a hexagonal shape are arranged as shown in FIG. 6. The PENTILE® pixel arrangement structure may be referred to as an RGBG matrix structure (e.g., a PENTILE® matrix structure or an RGBG structure (e.g., a PENTILE® structure)). PENTILE® is a registered trademark of Samsung Display Co., Ltd., Republic of Korea.

FIG. 7 is a cross-sectional view illustrating an example of a display panel taken along the line X1-X1′ of FIG. 5.

Referring to FIG. 7, the display panel 100 may include a semiconductor backplane SBP, a light emitting element backplane EBP, a display element layer EML, an encapsulation layer TFE, an organic film APL, an optical layer OPL, a cover layer CVL, and a polarizing plate POL.

The semiconductor backplane SBP may include a semiconductor substrate SSUB including a plurality of pixel transistors PTR, a plurality of semiconductor insulating films covering the plurality of pixel transistors PTR, and a plurality of contact terminals CTE electrically connected to the plurality of pixel transistors PTR, respectively. The plurality of pixel transistors PTR may be the first to sixth transistors T1 to T6 (see FIG. 3) described with reference to FIG. 3.

The semiconductor substrate SSUB may be a silicon substrate, a germanium substrate, and/or a silicon-germanium substrate. The semiconductor substrate SSUB may be a substrate doped with a first type impurity. A plurality of well regions WA may be disposed on the top surface of the semiconductor substrate SSUB. The plurality of well regions WA may be regions doped with a second type impurity. The second type impurity may be different from the aforementioned first type impurity. For example, when the first type impurity is a p-type impurity, the second type impurity may be an n-type impurity. Alternatively, when the first type impurity is an n-type impurity, the second type impurity may be a p-type impurity.

Each of the plurality of well regions WA may include a source region SA corresponding to the source electrode of the pixel transistor PTR, a drain region DA corresponding to the drain electrode thereof, and a channel region CH disposed between the source region SA and the drain region DA.

A lower insulating film BINS may be disposed between a gate electrode GE and the well region WA. A side insulating film SINS may be disposed on the side surface of the gate electrode GE. The side insulating film SINS may be disposed on the lower insulating film BINS.

Each of the source region SA and the drain region DA may be a region doped with the first type impurity. The gate electrode GE of the pixel transistor PTR may overlap the well region WA in the third direction DR3. The channel region CH may overlap the gate electrode GE in the third direction DR3. The source region SA may be disposed on one side of the gate electrode GE, and the drain region DA may be disposed on the other side of the gate electrode GE.

Each of the plurality of well regions WA may further include a first low-concentration impurity region LDD1 disposed between the channel region CH and the source region SA, and a second low-concentration impurity region LDD2 disposed between the channel region CH and the drain region DA. The first low-concentration impurity region LDD1 may be a region having a lower impurity concentration than the source region SA due to the lower insulating film BINS. The second low-concentration impurity region LDD2 may be a region having a lower impurity concentration than the drain region DA due to the lower insulating film BINS. The distance between the source region SA and the drain region DA may increase due to the presence of the first low-concentration impurity region LDD1 and the second low-concentration impurity region LDD2. Therefore, the length of the channel region CH of each of the pixel transistors PTR increases, so that punch-through and hot carrier phenomena that might be caused by a short channel are prevented.

A first semiconductor insulating film SINS1 may be disposed on the semiconductor substrate SSUB and the pixel transistors PTR. The first semiconductor insulating film SINS1 may be formed of silicon carbonitride (SiCN) and/or a silicon oxide (SiOx)-based inorganic film, but the present disclosure is not limited thereto.

A second semiconductor insulating film SINS2 may be disposed on the first semiconductor insulating film SINS1. The second semiconductor insulating film SINS2 may be formed of a silicon oxide (SiOx)-based inorganic film, but the present disclosure is not limited thereto.

The plurality of contact terminals CTE may be disposed on the second semiconductor insulating film SINS2. Each of the plurality of contact terminals CTE may be connected to the gate electrode GE, the source region SA, or the drain region DA of each of the pixel transistors PTR through holes penetrating the first semiconductor insulating film SINS1 and the second semiconductor insulating film SINS2. The plurality of contact terminals CTE may be formed of copper (Cu), aluminum (Al), tungsten (W), molybdenum (Mo), chromium (Cr), gold (Au), titanium (Ti), nickel (Ni), and/or neodymium (Nd), and/or an alloy including one or more of them.

A third semiconductor insulating film SINS3 may be disposed on a side surface of each of the plurality of contact terminals CTE on the second semiconductor insulating film SINS2. The top surface of each of the plurality of contact terminals CTE may be exposed without being covered by the third semiconductor insulating film SINS3. The third semiconductor insulating film SINS3 may be formed of a silicon oxide (SiOx)-based inorganic film, but the present disclosure is not limited thereto.

The semiconductor substrate SSUB may be replaced with a glass substrate and/or a polymer resin substrate such as polyimide. In this case, thin film transistors may be disposed on the glass substrate and/or the polymer resin substrate. The glass substrate may be a rigid substrate that does not bend, and the polymer resin substrate may be a flexible substrate that can be bent and/or curved.

The light emitting element backplane EBP may include a plurality of conductive layers ML1 to ML8, a plurality of vias VA1 to VA9, and a plurality of insulating films INS1 to INS9.

The first to eighth conductive layers ML1 to ML8 serve to connect the plurality of contact terminals CTE exposed from the semiconductor backplane SBP to thereby implement the pixel circuit of the first sub-pixel SP1 shown in FIG. 4. For example, the first to sixth transistors T1 to T6 are merely disposed on the semiconductor backplane SBP, and the connection line of the first to sixth transistors T1 to T6 and the first capacitor CP1 and the second capacitor CP2 may be disposed in the first to eighth conductive layers ML1 to ML8. In addition, a connection portion between the drain region corresponding to the drain electrode of the fourth transistor T4, the source region corresponding to the source electrode of the fifth transistor T5, and the first electrode of the light emitting element LE may also be disposed in the first to eighth conductive layers ML1 to ML8.

The first insulating film INS1 may be disposed on the semiconductor backplane SBP. Each of the first vias VA1 may penetrate the first insulating film INS1 and may be connected to the contact terminal CTE exposed from the semiconductor backplane SBP. Each of the first conductive layers ML1 may be disposed on the first insulating film INS1 and may be connected to the first via VA1.

The second insulating film INS2 may be disposed on the first insulating film INS1 and the first conductive layers ML1. Each of the second vias VA2 may penetrate the second insulating film INS2 and may be connected to the exposed first conductive layer ML1. Each of the second conductive layers ML2 may be disposed on the second insulating film INS2 and may be connected to the second via VA2.

The third insulating film INS3 may be disposed on the second insulating film INS2 and the second conductive layers ML2. Each of the third vias VA3 may penetrate the third insulating film INS3 and may be connected to the exposed second conductive layer ML2. Each of the third conductive layers ML3 may be disposed on the third insulating film INS3 and may be connected to the third via VA3.

A fourth insulating film INS4 may be disposed on the third insulating film INS3 and the third conductive layers ML3. Each of the fourth vias VA4 may penetrate the fourth insulating film INS4 and may be connected to the exposed third conductive layer ML3. Each of the fourth conductive layers ML4 may be disposed on the fourth insulating film INS4 and may be connected to the fourth via VA4.

A fifth insulating film INS5 may be disposed on the fourth insulating film INS4 and the fourth conductive layers ML4. Each of the fifth vias VA5 may penetrate the fifth insulating film INS5 and may be connected to the exposed fourth conductive layer ML4. Each of the fifth conductive layers ML5 may be disposed on the fifth insulating film INS5 and may be connected to the fifth via VA5.

A sixth insulating film INS6 may be disposed on the fifth insulating film INS5 and the fifth conductive layers ML5. Each of the sixth vias VA6 may penetrate the sixth insulating film INS6 and may be connected to the exposed fifth conductive layer ML5. Each of the sixth conductive layers ML6 may be disposed on the sixth insulating film INS6 and may be connected to the sixth via VA6.

A seventh insulating film INS7 may be disposed on the sixth insulating film INS6 and the sixth conductive layers ML6. Each of the seventh vias VA7 may penetrate the seventh insulating film INS7 and may be connected to the exposed sixth conductive layer ML6. Each of the seventh conductive layers ML7 may be disposed on the seventh insulating film INS7 and may be connected to the seventh via VA7.

An eighth insulating film INS8 may be disposed on the seventh insulating film INS7 and the seventh conductive layers ML7. Each of the eighth vias VA8 may penetrate the eighth insulating film INS8 and may be connected to the exposed seventh conductive layer ML7. Each of the eighth conductive layers ML8 may be disposed on the eighth insulating film INS8 and may be connected to the eighth via VA8.

The first to eighth conductive layers ML1 to ML8 and the first to eighth vias VA1 to VA8 may be formed of substantially the same material. The first to eighth conductive layers ML1 to ML8 and the first to eighth vias VA1 to VA8 may be formed of copper (Cu), aluminum (Al), tungsten (W), molybdenum (Mo), chromium (Cr), gold (Au), titanium (Ti), nickel (Ni), and/or neodymium (Nd), and/or an alloy including one or more of them. First to eighth insulating films INS1 to INS8 may be formed of a silicon oxide (SiOx)-based inorganic film, but the present disclosure is not limited thereto.

The thicknesses of the first conductive layer ML1, the second conductive layer ML2, the third conductive layer ML3, the fourth conductive layer ML4, the fifth conductive layer ML5, and the sixth conductive layer ML6 may be greater than the thicknesses of the first via VA1, the second via VA2, the third via VA3, the fourth via VA4, the fifth via VA5, and the sixth via VA6, respectively. The thickness of each of the second conductive layer ML2, the third conductive layer ML3, the fourth conductive layer ML4, the fifth conductive layer ML5, and the sixth conductive layer ML6 may be greater than the thickness of the first conductive layer ML1. The thickness of the second conductive layer ML2, the thickness of the third conductive layer ML3, the thickness of the fourth conductive layer ML4, the thickness of the fifth conductive layer ML5, and the thickness of the sixth conductive layer ML6 may be substantially the same. For example, the thickness of the first conductive layer ML1 is approximately 1360 Å. The thickness of each of the second conductive layer ML2, the third conductive layer ML3, the fourth conductive layer ML4, the fifth conductive layer ML5, and the sixth conductive layer ML6 is approximately 1440 Å. The thickness of each of the first via VA1, the second via VA2, the third via VA3, the fourth via VA4, the fifth via VA5, and the sixth via VA6 is approximately 1150 Å. However, the thicknesses of the first to sixth conductive layers ML1, ML2, ML3, ML4, ML5, and ML6 and the first to sixth vias VA1, VA2, VA3, VA4, VA5, and VA6 are not limited thereto.

The thickness of each of the seventh conductive layer ML7 and the eighth conductive layer ML8 may be greater than the thickness of each of the first conductive layer ML1, the second conductive layer ML2, the third conductive layer ML3, the fourth conductive layer ML4, the fifth conductive layer ML5, and the sixth conductive layer ML6. The thickness of the seventh conductive layer ML7 and the thickness of the eighth conductive layer ML8 may be greater than the thickness of the seventh via VA7 and the thickness of the eighth via VA8, respectively. The thickness of each of the seventh via VA7 and the eighth via VA8 may be greater than the thickness of each of the first via VA1, the second via VA2, the third via VA3, the fourth via VA4, the fifth via VA5, and the sixth via VA6. The thickness of the seventh conductive layer ML7 and the thickness of the eighth conductive layer ML8 may be substantially the same. For example, the thickness of each of the seventh conductive layer ML7 and the eighth conductive layer ML8 is approximately 9000 Å, and the thickness of each of the seventh via VA7 and the eighth via VA8 is approximately 6000 Å. However, the thicknesses of the seventh conductive layer ML7, the eighth conductive layer ML8, the seventh via VA7, and the eighth via VA8 are not limited thereto.

A ninth insulating film INS9 may be disposed on the eighth insulating film INS8 and the eighth conductive layer ML8. The ninth insulating film INS9 may be formed of a silicon oxide (SiOₓ)-based inorganic film, but the present disclosure is not limited thereto.

Each of the ninth vias VA9 may penetrate the ninth insulating film INS9 and may be connected to the exposed eighth conductive layer ML8. The ninth vias VA9 may be formed of copper (Cu), aluminum (Al), tungsten (W), molybdenum (Mo), chromium (Cr), gold (Au), titanium (Ti), nickel (Ni), and/or neodymium (Nd), and/or an alloy including one or more of them.

The display element layer EML may be disposed on the light emitting element backplane EBP. The display element layer EML may include light emitting elements LE each including a reflective electrode layer RL, tenth and eleventh insulating films INS10 and INS11, a tenth via VA10, a first electrode AND, a light emitting stack IL, and a second electrode CAT; a pixel defining film PDL; and a plurality of trenches TRC.

The reflective electrode layer RL may be disposed on the ninth insulating film INS9. The reflective electrode layer RL may include at least one reflective electrode RL1, RL2, RL3, and RL4. For example, the reflective electrode layer RL may include first to fourth reflective electrodes RL1, RL2, RL3, and RL4 as shown in FIG. 7, but is not limited thereto.

Each of the first reflective electrodes RL1 may be disposed on the ninth insulating film INS9, and may be connected to the ninth via VA9. The first reflective electrodes RL1 may be formed of copper (Cu), aluminum (Al), tungsten (W), molybdenum (Mo), chromium (Cr), gold (Au), titanium (Ti), nickel (Ni), and/or neodymium (Nd), and/or an alloy including one or more of them. For example, the first reflective electrodes RL1 may contain titanium nitride (TiN).

Each of the second reflective electrodes RL2 may be disposed on the first reflective electrode RL1. The second reflective electrodes RL2 may be formed of copper (Cu), aluminum (Al), tungsten (W), molybdenum (Mo), chromium (Cr), gold (Au), titanium (Ti), nickel (Ni), and/or neodymium (Nd), and/or an alloy including one or more of them. For example, the second reflective electrodes RL2 may include aluminum (Al).

Each of the third reflective electrodes RL3 may be disposed on the second reflective electrode RL2. The third reflective electrodes RL3 may be formed of copper (Cu), aluminum (Al), tungsten (W), molybdenum (Mo), chromium (Cr), gold (Au), titanium (Ti), nickel (Ni), and/or neodymium (Nd), and/or an alloy including one or more of them. For example, the third reflective electrodes RL3 may contain titanium nitride (TiN).

Each of the fourth reflective electrodes RL4 may be disposed on the third reflective electrode RL3. The fourth reflective electrodes RL4 may be formed of copper (Cu), aluminum (Al), tungsten (W), molybdenum (Mo), chromium (Cr), gold (Au), titanium (Ti), nickel (Ni), and/or neodymium (Nd), and/or an alloy including one or more of them. For example, the fourth reflective electrodes RL4 may include titanium (Ti).

Because, in one or more embodiments, the second reflective electrode RL2 is an electrode that substantially reflects light from the light emitting elements LE, the thickness of the second reflective electrode RL2 may be greater than the thickness of each of the first reflective electrode RL1, the third reflective electrode RL3, and the fourth reflective electrode RL4. For example, the thickness of each of the first reflective electrode RL1, the third reflective electrode RL3, and the fourth reflective electrode RL4 is approximately 100 Å, and the thickness of the second reflective electrode RL2 is approximately 850 Å. However, the thicknesses of the first to fourth reflective electrodes RL1, RL2, RL3, and RL4 are not limited thereto. For example, as shown in FIG. 7, because, the fourth reflective electrode RL4 is an electrode that substantially reflects light from the light emitting elements LE, the thickness of the fourth reflective electrode RL4 may be greater than the thickness of each of the first reflective electrode RL1, the second reflective electrode RL2, and the third reflective electrode RL3.

The tenth insulating film INS10 may be disposed on the ninth insulating film INS9. The tenth insulating film INS10 may be disposed between the reflective electrode layers RL adjacent to each other in a horizontal direction. The tenth insulating film INS10 may be formed of a silicon oxide (SiOx)-based inorganic film, but the present disclosure is not limited thereto. In one or more embodiments, the tenth insulating film INS10 may be disposed not only between the reflective electrode layers RL but also on the reflective electrode layer RL.

The eleventh insulating film INS11 may be disposed on the tenth insulating film INS10 and the reflective electrode layer RL. The eleventh insulating film INS11 may be formed of a silicon oxide (SiOx)-based inorganic film, but the present disclosure is not limited thereto. The tenth insulating film INS10 and the eleventh insulating film INS11 may be an optical auxiliary layer through which light reflected by the reflective electrode layer RL passes, from among light emitted from the light emitting elements LE.

In one or more embodiments, in at least one sub-pixel selected from among the first sub-pixel SP1, the second sub-pixel SP2, and the third sub-pixel SP3, in order to adjust the resonance distance of light emitted from the light emitting elements LE, the total thickness of the insulating film disposed between the first electrode AND and the reflective electrode layer RL may be different in the first sub-pixel SP1, the second sub-pixel SP2, and the third sub-pixel SP3.

In one or more embodiments, as shown in the drawing, when the tenth insulating film INS10 is not disposed between the first electrode AND and the reflective electrode layer RL but the eleventh insulating film INS11 is disposed therebetween, the thickness of the eleventh insulating film INS11 disposed in each of the first sub-pixel SP1, the second sub-pixel SP2, and the third sub-pixel SP3 may be different. For example, the thickness of the eleventh insulating film INS11 disposed in the first sub-pixel SP1 may be less than the thickness of the eleventh insulating film INS11 disposed in the second sub-pixel SP2, and the thickness of the eleventh insulating film INS11 disposed in the second sub-pixel SP2 may be less than the thickness of the eleventh insulating film INS11 disposed in the third sub-pixel SP3.

In one or more embodiments, in the first sub-pixel SP1, neither the tenth insulating film INS10 nor the eleventh insulating film INS11 may be disposed between the first electrode AND and the reflective electrode layer RL, and in the sub-pixel SP2, the tenth insulating film INS10 and/or the eleventh insulating film INS11 may be disposed between the first electrode AND and the reflective electrode layer RL, and in the third sub-pixel SP3, both the tenth insulating film INS10 and the eleventh insulating film INS11 may be disposed between the first electrode AND and the reflective electrode layer RL.

In one or more embodiments, a twelfth insulating film may be further disposed between the first electrode AND and the reflective electrode layer RL. In this case, in the first sub-pixel SP1, the tenth insulating film INS10, the eleventh insulating film INS11, and/or the twelfth insulating film may be disposed between the first electrode AND and the reflective electrode layer RL, in the second sub-pixel SP2, two of the tenth insulating film INS10, the eleventh insulating film INS11, and the twelfth insulating film may be disposed between the first electrode AND and the reflective electrode layer RL, and in the third sub-pixel SP3, all of the tenth insulating film INS10, the eleventh insulating film INS11, and the twelfth insulating film may be disposed between the first electrode AND and the reflective electrode layer RL.

In summary, the distance between the first electrode AND and the reflective electrode layer RL may be different in the first sub-pixel SP1, the second sub-pixel SP2, and the third sub-pixel SP3. That is, in order to adjust the distance from the reflective electrode layer RL to the second electrode CAT according to the main wavelength of the light emitted from each of the first sub-pixel SP1, the second sub-pixel SP2, and the third sub-pixel SP3, the presence/absence or thickness of the tenth insulating film INS10 and the eleventh insulating film INS11 may be set in each of the first sub-pixel SP1, the second sub-pixel SP2, and the third sub-pixel SP3.

Although it is illustrated in the drawing that the total thickness of the insulating film disposed between the first electrode AND and the reflective electrode layer RL increases in the order of the first sub-pixel SP1, the second sub-pixel SP2, and the third sub-pixel SP3, the present disclosure is not limited thereto. That is, it is illustrated that the distance between the first electrode AND and the reflective electrode layer RL in the third sub-pixel SP3 is greater than the distance between the first electrode AND and the reflective electrode layer RL in the second sub-pixel SP2 and the distance between the first electrode AND and the reflective electrode layer RL in the first sub-pixel SP1, and the distance between the first electrode AND and the reflective electrode layer RL in the second sub-pixel SP2 is greater than the distance between the first electrode AND and the reflective electrode layer RL in the first sub-pixel SP1, but the present disclosure is not limited thereto. The size relationship of the total thickness of the insulating film disposed between the first electrode AND and the reflective electrode layer RL in each of the first sub-pixel SP1, the second sub-pixel SP2, and the third sub-pixel SP3 may be variously changed depending on the resonance distance.

Each of the tenth vias VA10 may be connected to reflective electrode layer RL exposed through the tenth insulating film INS10 and/or the eleventh insulating film INS11. The tenth vias VA10 may be formed of copper (Cu), aluminum (Al), tungsten (W), molybdenum (Mo), chromium (Cr), gold (Au), titanium (Ti), nickel (Ni), and/or neodymium (Nd), and/or an alloy including one or more of them. The thickness of the tenth via VA10 in the second sub-pixel SP2 may be less than the thickness of the tenth via VA10 in the third sub-pixel SP3, and the thickness of the tenth via VA10 in the first sub-pixel SP1 may be less than the thickness of the tenth via VA10 in the second sub-pixel SP2, but the present disclosure is not limited thereto.

The first electrode AND of each of the light emitting elements LE may be disposed on the eleventh interlayer insulating film INS11 and connected to the tenth via VA10. The first electrode AND of each of the light emitting elements LE may be connected to the drain region DA or source region SA of the pixel transistor PTR through the tenth via VA10, the first to fourth reflective electrodes RL1 to RL4, the first to ninth vias VA1 to VA9, the first to eighth conductive layers ML1 to ML8, and the contact terminal CTE. The first electrode AND of each of the light emitting elements LE may be formed of copper (Cu), aluminum (Al), tungsten (W), molybdenum (Mo), chromium (Cr), gold (Au), titanium (Ti), nickel (Ni), and/or neodymium (Nd), or an alloy including one or more of them. For example, the first electrode AND of each of the light emitting elements LE may be titanium nitride (TiN).

The pixel defining film PDL may be disposed on a part of the first electrode AND of each of the light emitting elements LE. The pixel defining film PDL may cover the edge of the first electrode AND of each of the light emitting elements LE. The pixel defining film PDL may serve to partition the first emission areas EA1, the second emission areas EA2, and the third emission areas EA3.

The first emission area EA1 may be defined as an area in which the first electrode AND, the light emitting stack IL, and the second electrode CAT are sequentially stacked in the first sub-pixel SP1 to emit light. The second emission area EA2 may be defined as an area in which the first electrode AND, the light emitting stack IL, and the second electrode CAT are sequentially stacked in the second sub-pixel SP2 to emit light. The third emission area EA3 may be defined as an area in which the first electrode AND, the light emitting stack IL, and the second electrode CAT are sequentially stacked in the third sub-pixel SP3 to emit light.

The pixel defining film PDL may include first to third pixel defining films PDL1, PDL2, and PDL3. The first pixel defining film PDL1 may be disposed on the edge of the first electrode AND of each of the light emitting elements LE, the second pixel defining film PDL2 may be disposed on the first pixel defining film PDL1, and the third pixel defining film PDL3 may be disposed on the second pixel defining film PDL2. The first pixel defining film PDL1, the second pixel defining film PDL2, and the third pixel defining film PDL3 may be formed of a silicon oxide (SiOₓ)-based inorganic film, but the present disclosure is not limited thereto. The first pixel defining film PDL1, the second pixel defining film PDL2, and the third pixel defining film PDL3 may each have a thickness of about 500 Å.

When the first pixel defining film PDL1, the second pixel defining film PDL2, and the third pixel defining film PDL3 are formed as one pixel defining film, the height of the one pixel defining film increases, so that a first encapsulation inorganic film TFE1 may be cut off due to step coverage. Step coverage refers to the ratio of the degree of thin film coated on an inclined portion to the degree of thin film coated on a flat portion. The lower the step coverage, the more likely it is that the thin film will be cut off at inclined portions.

Therefore, in order to reduce or prevent the likelihood of the first encapsulation inorganic film TFE1 being cut off due to the step coverage, the first pixel defining film PDL1, the second pixel defining film PDL2, and the third pixel defining film PDL3 may have a cross-sectional structure having a stepped portion. For example, the width of the first pixel defining film PDL1 may be greater than the width of the second pixel defining film PDL2 and the width of the third pixel defining film PDL3, and the width of the second pixel defining film PDL2 may be greater than the width of the third pixel defining film PDL3. Each of the width of the first pixel defining film PDL1, the width of the second pixel defining film PDL2, and the width of the third pixel defining film PDL3 refers to the length in the horizontal direction perpendicular to the third direction DR3.

Each of the plurality of trenches TRC may penetrate the first pixel defining film PDL1, the second pixel defining film PDL2, and the third pixel defining film PDL3. Furthermore, each of the plurality of trenches TRC may penetrate the eleventh insulating film INS11. The eleventh insulating film INS11 may be at least partially recessed at each of the plurality of trenches TRC.

At least one trench TRC may be disposed between the neighboring sub-pixels SP1, SP2, and SP3. Although FIG. 7 illustrates that two trenches TRC are disposed between the neighboring sub-pixels SP1, SP2, and SP3, the present disclosure is not limited thereto.

The light emitting stack IL may include a plurality of intermediate layers. FIG. 7 illustrates that the light emitting stack IL has a three-tandem structure including a first stack layer IL1, a second stack layer IL2, and a third stack layer IL3, but the present disclosure is not limited thereto. For example, the light emitting stack IL may have a two-tandem structure including two intermediate layers.

In the three-tandem structure, the light emitting stack IL may have a tandem structure including a plurality of stack layers IL1, IL2, and IL3 that emit different lights. For example, the light emitting stack IL may include the first stack layer IL1 that emits light of the first color, the second stack layer IL2 that emits light of the third color, and the third stack layer IL3 that emits light of the second color. The first stack layer IL1, the second stack layer IL2, and the third stack layer IL3 may be sequentially stacked.

The first stack layer IL1 may have a structure in which a first hole transport layer, a first organic light emitting layer that emits light of the first color, and a first electron transport layer are sequentially stacked. The second stack layer IL2 may have a structure in which a second hole transport layer, a second organic light emitting layer that emits light of the third color, and a second electron transport layer are sequentially stacked. The third stack layer IL3 may have a structure in which a third hole transport layer, a third organic light emitting layer that emits light of the second color, and a third electron transport layer are sequentially stacked.

A first charge generation layer for supplying charges to the second stack layer IL2 and supplying electrons to the first stack layer IL1 may be disposed between the first stack layer IL1 and the second stack layer IL2. The first charge generation layer may include an N-type charge generation layer that supplies electrons to the first stack layer IL1 and a P-type charge generation layer that supplies holes to the second stack layer IL2. The N-type charge generation layer may include a dopant of a metal material.

A second charge generation layer for supplying charges to the third stack layer IL3 and supplying electrons to the second stack layer IL2 may be disposed between the second stack layer IL2 and the third stack layer IL3. The second charge generation layer may include an N-type charge generation layer that supplies electrons to the second stack layer IL2 and a P-type charge generation layer that supplies holes to the third stack layer IL3.

The first stack layer IL1 may be disposed on the first electrodes AND and the pixel defining film PDL, and may be disposed on the bottom surface of each trench TRC. Due to the trench TRC, the first stack layer IL1 may be cut off between the neighboring sub-pixels SP1, SP2, and SP3. The second stack layer IL2 may be disposed on the first stack layer IL1. Due to the trench TRC, the second stack layer IL2 may be cut off between the neighboring sub-pixels SP1, SP2, and SP3. A cavity ESS or an empty space may be disposed between the first stack layer IL1 and the second stack layer IL2. The third stack layer IL3 may be disposed on the second stack layer IL2. The third stack layer IL3 is not cut off by the trench TRC and may be disposed to cover the second stack layer IL2 in each of the trenches TRC. That is, in the three-tandem structure, each of the plurality of trenches TRC may be a structure for cutting off the first and second stack layers IL1 and IL2, the first charge generation layer, and the second charge generation layer of the display element layer EML between the neighboring sub-pixels SP1, SP2, and SP3. In addition, in the two-tandem structure, each of the trenches TRC may be a structure for cutting off the charge generation layer disposed between a lower intermediate layer and an upper intermediate layer, and the lower intermediate layer.

In order to stably cut off the first and second stack layers IL1 and IL2 of the display element layer EML between the neighboring sub-pixels SP1, SP2, and SP3, the height of each of the plurality of trenches TRC may be greater than the height of the pixel defining film PDL. The height of each of the plurality of trenches TRC refers to the length of each of the plurality of trenches TRC in the third direction DR3. The height of the pixel defining film PDL refers to the length of the pixel defining film PDL in the third direction DR3. In order to cut off the first to third stack layers IL1, IL2, and IL3 of the display element layer EML between the neighboring sub-pixels SP1, SP2, and SP3, another structure may exist instead of the trench TRC. For example, instead of the trench TRC, a reverse-tapered partition wall may be disposed on the pixel defining film PDL.

The number of the stack layers IL1, IL2, and IL3 that emit different lights is not limited to that shown in FIG. 7. For example, the light emitting stack IL may include two intermediate layers. In this case, one of the two intermediate layers may be substantially the same as the first stack layer IL1, and the other may include a second hole transport layer, a second organic light emitting layer, a third organic light emitting layer, and a second electron transport layer. In this case, a charge generation layer for supplying electrons to one intermediate layer and supplying charges to the other intermediate layer may be disposed between the two intermediate layers.

In addition, FIG. 7 illustrates that the first to third stack layers IL1, IL2, and IL3 are all disposed in the first emission area EA1, the second emission area EA2, and the third emission area EA3, but the present disclosure is not limited thereto. For example, the first stack layer IL1 may be disposed in the first emission area EA1, and may be omitted from the second emission area EA2 and the third emission area EA3. Furthermore, the second stack layer IL2 may be disposed in the second emission area EA2 and may be omitted from the first emission area EA1 and the third emission area EA3. Further, the third stack layer IL3 may be disposed in the third emission area EA3 and may be omitted from the first emission area EA1 and the second emission area EA2. In this case, first to third color filters CF1, CF2, and CF3 of the optical layer OPL may be omitted.

The second electrode CAT may be disposed on the third stack layer IL3. The second electrode CAT may be disposed on the third stack layer IL3 in each of the plurality of trenches TRC. The second electrode CAT may be formed of a transparent conductive material (TCO) such as ITO or IZO that can transmit light or a semi-transmissive conductive material such as magnesium (Mg), silver (Ag), or an alloy of Mg and Ag. When the second electrode CAT is formed of a semi-transmissive conductive material, the light emission efficiency may be improved in each of the first to third sub-pixels SP1, SP2, and SP3 due to a micro-cavity effect.

The encapsulation layer TFE may be disposed on the display element layer EML. The encapsulation layer TFE may include at least one inorganic film TFE1 and TFE2 to reduce or prevent oxygen and/or moisture from permeating into the display element layer EML. For example, the encapsulation layer TFE may include a first encapsulation inorganic film TFE1, and a second encapsulation inorganic film TFE2.

The first encapsulation inorganic film TFE1 may be disposed on the second electrode CAT. The first encapsulation inorganic film TFE1 may be formed as a multilayer in which one or more inorganic films selected from silicon nitride (SiNx), silicon oxy nitride (SiON), and/or silicon oxide (SiOx) are alternately stacked. The first encapsulation inorganic film TFE1 may be formed by a chemical vapor deposition (CVD) process.

The second encapsulation inorganic film TFE2 may be disposed on the first encapsulation inorganic film TFE1. The second encapsulation inorganic film TFE2 may be formed of titanium oxide (TiOx) and/or aluminum oxide (AIOx), but the present disclosure is not limited thereto. The second encapsulation inorganic film TFE2 may be formed by an atomic layer deposition (ALD) process. The thickness of the second encapsulation inorganic film TFE2 may be less than the thickness of the first encapsulation inorganic film TFE1.

The display panel 100 may further include an organic film APL. The organic film APL may be a layer for increasing the interfacial adhesion between the encapsulation layer TFE and the optical layer OPL. The organic film APL may be an organic film such as acrylic resin, epoxy resin, phenolic resin, polyamide resin, and/or polyimide resin.

The optical layer OPL may include a plurality of color filters CF1, CF2, and CF3, a plurality of lenses LNS, and a filling layer FIL. The plurality of color filters CF1, CF2, and CF3 may include the first to third color filters CF1, CF2, and CF3. The first to third color filters CF1, CF2, and CF3 may be disposed on the organic film APL.

The first color filter CF1 may overlap the first emission area EA1 of the first sub-pixel SP1. The first color filter CF1 may transmit light of the first color, i.e., light of a red wavelength band. The red wavelength band may be approximately 600 nm to 750 nm. Thus, the first color filter CF1 may transmit light of the first color from among light emitted from the first emission area EA1.

The second color filter CF2 may overlap the second emission area EA2 of the second sub-pixel SP2. The second color filter CF2 may transmit light of the second color, i.e., light of a green wavelength band. The green wavelength band may be approximately 480 nm to 560 nm. Thus, the second color filter CF2 may transmit light of the second color from among light emitted from the second emission area EA2.

The third color filter CF3 may overlap the third emission area EA3 of the third sub-pixel SP3. The third color filter CF3 may transmit light of the third color, i.e., light of a blue wavelength band. The blue wavelength band may be approximately 370 nm to 460 nm. Thus, the third color filter CF3 may transmit light of the third color from among light emitted from the third emission area EA3.

The plurality of lenses LNS may be disposed on the first color filter CF1, the second color filter CF2, and the third color filter CF3, respectively. Each of the plurality of lenses LNS may be a structure for increasing the proportion of light directed to the front of the display device 10. Each of the plurality of lenses LNS may have a cross-sectional shape that is convex in an upward direction. In one or more embodiments, the plurality of lenses LNS may be a micro lens array (MLA).

The filling layer FIL may be disposed on the plurality of lenses LNS. The filling layer FIL may have a suitable refractive index (e.g., a predetermined refractive index) such that light travels in the third direction DR3 at an interface between the filling layer FIL and the plurality of lenses LNS. Further, the filling layer FIL may be a planarization layer. The filling layer FIL may be an organic film such as acrylic resin, epoxy resin, phenolic resin, polyamide resin, or polyimide resin.

The cover layer CVL may be disposed on the filling layer FIL. The cover layer CVL may be a glass substrate and/or a polymer resin. When the cover layer CVL is a glass substrate, it may be attached onto the filling layer FIL. In this case, the filling layer FIL serves to bond the cover layer CVL. When the cover layer CVL is a glass substrate, it may serve as an encapsulation substrate. When the cover layer CVL is a polymer resin, it may be directly applied onto the filling layer FIL.

The polarizing plate POL may be disposed on one surface of the cover layer CVL. The polarizing plate POL may be a structure for reducing or preventing visibility degradation caused by reflection of external light. The polarizing plate POL may include a linear polarizing plate and a phase retardation film. For example, the phase retardation film may be a λ/4 plate (quarter-wave plate), but the present disclosure is not limited thereto. However, when visibility degradation caused by reflection of external light is sufficiently overcome by the first to third color filters CF1, CF2, and CF3, the polarizing plate POL may be omitted.

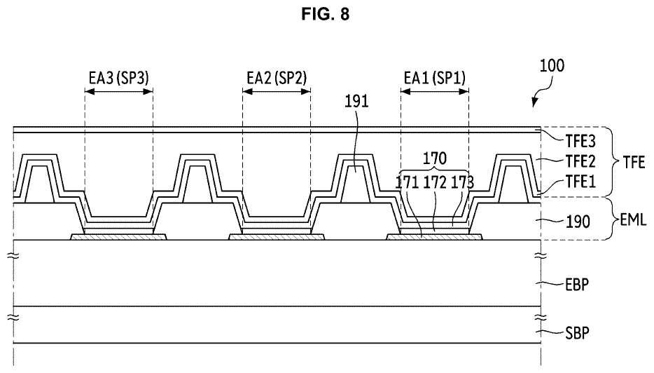

FIG. 8 is a cross-sectional view showing another example of a display panel included in a display device according to one or more embodiments.

Referring to FIG. 8 in addition to FIG. 7, in one or more embodiments, the display device 10 may include the display panel 100 according to the embodiment of FIG. 8 instead of the display panel 100 described with reference to FIG. 7.

The display panel 100 according to the embodiment of FIG. 8 may include a semiconductor backplane SBP, a light emitting element backplane EBP, a display element layer EML, and an encapsulation layer TFE. However, the present disclosure is not limited thereto, and the display panel 100 according to the embodiment of FIG. 8 may further include, like the display panel 100 described with reference to FIG. 7, the optical layer OPL, the cover layer CVL, and the polarizing plate POL on the encapsulation layer TFE.

Descriptions of the semiconductor backplane SBP and the light emitting element backplane EBP are omitted here because they are the same as those of the display panel 100 described with reference to FIG. 7.

The display element layer EML may be disposed on the light emitting element backplane EBP. The display element layer EML may include light emitting elements 170 and a bank 190. Each of the light emitting elements 170 may include a first light emitting electrode 171, the light emitting layer 172, and a second light emitting electrode 173.

The first light emitting electrode 171 may be disposed on the light emitting element backplane EBP. For example, in one or more embodiments, the first light emitting electrode 171 may be connected to the eighth conductive layer ML8 through the ninth via VA9 that penetrates the ninth insulating film INS9 and exposes the eighth conductive layer ML8.

In a top emission structure in which light is emitted toward the second light emitting electrode 173 when viewed with respect to the light emitting layer 172, the first light emitting electrode 171 may be formed of a metal material having high reflectivity to have a stacked structure (Ti/Al/Ti) of aluminum and titanium, a stacked structure (ITO/AI/ITO) of aluminum and ITO, an APC alloy, and a stacked structure (ITO/APC/ITO) of an APC alloy and ITO. The APC alloy is an alloy of silver (Ag), palladium (Pd) and copper (Cu).

The bank 190 may be disposed to separate the first light emitting electrodes 171 to define the emission areas EA1, EA2, and EA3. The bank 190 may be disposed to cover a part of the edge of the first light emitting electrode 171. The bank 190 may be formed of an organic film such as acryl resin, epoxy resin, phenolic resin, polyamide resin, polyimide resin, and/or the like.

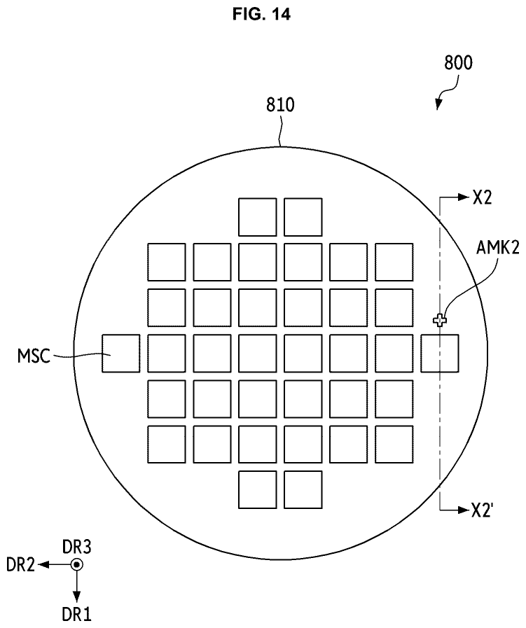

A spacer 191 may be disposed on the bank 190. The spacer 191 may function to support a deposition mask 800 (see FIG. 14) during the process of manufacturing the light emitting layer 172. The spacer 191 may be formed of an organic film such as acryl resin, epoxy resin, phenolic resin, polyamide resin, polyimide resin, and/or the like.

Each of the emission areas EA1, EA2, and EA3 represents an area in which the first light emitting electrode 171, the light emitting layer 172, and the second light emitting electrode 173 are sequentially stacked, and holes from the first light emitting electrode 171 and electrons from the second light emitting electrode 173 are combined with each other in the light emitting layer 172 to emit light.

In one or more embodiments, the light emitting layer 172 may be disposed on the first light emitting electrode 171. However, in one or more other embodiments, the light emitting layer 172 may be disposed on the first light emitting electrode 171 and the bank 190. The light emitting layer 172 may include an organic material to emit light in a suitable color (e.g., a predetermined color). For example, the light emitting layer 172 may include a hole transporting layer, an organic material layer, and/or an electron transporting layer.

The second light emitting electrode 173 may be disposed on the light emitting layer 172, the bank 190 and the spacer 191. The second light emitting electrode 173 may be formed to cover the light emitting layer 172. The second light emitting electrode 173 may be a common layer shared by all of the emission areas EA1, EA2, and EA3. In one or more embodiments, a capping layer may be formed on the second light emitting electrode 173.

In the top emission structure, the second light emitting electrode 173 may be formed of transparent conductive oxide (TCO) such as indium tin oxide (ITO) and indium zinc oxide (IZO) capable of transmitting light or a semi-transmissive conductive material such as magnesium (Mg), silver (Ag), or an alloy of magnesium (Mg) and silver (Ag). When the second light emitting electrode 173 is formed of a semi-transmissive conductive material, the light emission efficiency can be increased due to a micro-cavity effect.

An encapsulation layer TFE may be disposed on the second light emitting electrode 173. The encapsulation layer TFE may include at least one inorganic film to prevent oxygen and/or moisture from permeating into the light emitting element layer. In addition, the encapsulation layer TFE may include at least one organic layer to protect the light emitting element layer from foreign substances such as dust. For example, the encapsulation layer TFE may include a first encapsulation film TFE1, a second encapsulation film TFE2, and a third encapsulation film TFE3.

The first encapsulation film TFE1 (e.g., a first inorganic encapsulation film) may be disposed on the second light emitting electrode 173. The first encapsulation film TFE1 may be an inorganic film of a single layer or multiple layers. The first encapsulation film TFE1 may be formed as a single layer or a multilayer in which one or more inorganic films of a silicon nitride layer, a silicon oxynitride layer, a silicon oxide layer, a titanium oxide layer, and/or an aluminum oxide layer are alternately stacked.

The second encapsulation film TFE2 (e.g., a first organic encapsulation film) may be disposed on the first encapsulation film TFE1. The second encapsulation film TFE2 may be an organic layer of a single layer or multiple layers. The second encapsulation film TFE2 may include a polymer-based material. Polymer-based materials may include polyethylene terephthalate, polyethylene naphthalate, polycarbonate, polyimide, polyethylene sulfonate, polyoxymethylene, polyarylate, hexamethyldisiloxane, and/or acrylic resins (e.g., polymethyl methacrylate, polyacrylic acid, or the like), or any combination thereof.

The third encapsulation film TFE3 (e.g., a second inorganic encapsulation film) may be disposed on the second encapsulation film TFE2. The third encapsulation film TFE3 may be an inorganic film of a single layer or multiple layers. The third encapsulation film TFE3 may include the same material as the first encapsulation film TFE1. For example, the third encapsulation film TFE3 may be formed as a single layer or a multilayer in which one or more inorganic films of a silicon nitride layer, a silicon oxynitride layer, a silicon oxide layer, a titanium oxide layer and an aluminum oxide layer are alternately stacked.

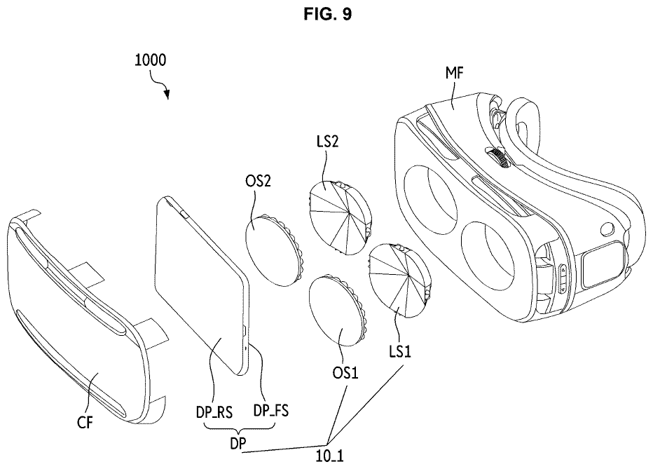

FIG. 9 is an exploded perspective view illustrating a head mounted display according to one or more embodiments.

Referring to FIG. 9, a head mounted display 1000 is formed in the form of glasses or a head mount to provide an image to a user using a display device 10_1.

The head mounted display 1000 may include a see-through type that provides augmented reality based on actual external objects and a see-closed type that provides virtual reality to the user on a screen independent from the external objects.

The head mounted display 1000 may include a main frame MF mounted on the user's body, the display device 10_1 mounted on the main frame MF to display an image, and a cover frame CF that covers the display device 10_1.

The display device 10_1 may be formed integrally with the head mounted display 1000 that may be carried by the user and easily attached to or detached from a face or a head, and may be formed to be assembled to the head mounted display 1000. The display device 10_1 may be substantially the same as the display device 10 described in conjunction with FIG. 1 and/or the like.

The display device 10_1 may include a display panel DP that displays an image, first and second lens frames OS1 and OS2 that refract an image display light, and first and second multi-channel lenses LS1 and LS2 that form an optical path so that the image display light of the display panel DP is visible to the user.

The main frame MF may be worn on the user's face and head. The main frame MF may be formed in a shape corresponding to the user's head and facial structure.

The main frame MF may be integrally formed with display device 10_1, that is, the display panel DP, the first and second lens frames OS1 and OS2, and the first and second multi-channel lenses LS1 and LS2. Alternatively, the display panel DP, the first and second lens frames OS1 and OS2, and the first and second multi-channel lenses LS1 and LS2 may be assembled and mounted to the main frame MF. To this end, the main frame MF may have a space or a structure for accommodating the display panel DP, the first and second lens frames OS1 and OS2, and the first and second multi-channel lenses LS1 and LS2. The main frame MF may further include a structure such as a strap or a band to facilitate the mounting, and a controller, an image processing unit, and a lens accommodating unit may be further included in the main frame MF.

The display panel DP may be divided into a front surface DP_FS where an image is displayed, and a rear surface DP_RS located on the opposite side of the front surface DP_FS. Image display light may be emitted from the front surface DP_FS of the display panel DP. As will be described later, the first and second lens frames OS1 and OS2 may be disposed on the front surface DP_FS of the display panel DP, and the first and second multi-channel lenses LS1 and LS2 may be disposed on the front surfaces of the first and second lens frames OS1 and OS2. In one or more embodiments, at least one infrared camera may be disposed on at least one of the front surface DP_FS or the rear surface DP_RS of the display panel DP. The display panel DP may be substantially the same as the display panel 100 described in conjunction with FIG. 1 and the like.

The display panel DP may be built in the main frame MF in a state where the first and second lens frames OS1 and OS2 and the first and second multi-channel lenses LS1 and LS2 are mounted and fixed, or may be detachably assembled to the main frame MF. The display panel DP may be opaque, transparent, or translucent depending on the design of the display device 10_1, for example, the usage type of the display device 10_1.

Each of the first and second lens frames OS1 and OS2 may have an area corresponding to the image display surface of the display panel DP, and may be formed in a shape corresponding to that of the image display surface. Further, the first and second lens frames OS1 and OS2 may be formed to have an area and a shape corresponding to those of the rear surfaces of the first and second multi-channel lenses LS1 and LS2, respectively. The rear surfaces of the first and second lens frames OS1 and OS2 may be attached to the image display surface of the display panel DP, and the first and second multi-channel lenses LS1 and LS2 may be attached to the front surfaces of the first and second lens frames OS1 and OS2, respectively. The first and second lens frames OS1 and OS2 refract the image display light emitted from the image display surface of the display panel DP at a suitable angle (e.g., a preset angle) and provide it to the first and second multi-channel lenses LS1 and LS2 disposed on the front surfaces thereof, respectively.

Specifically, the first and second lens frames OS1 and OS2 may refract the image display light, which is emitted from the image display surface of the display panel DP toward the front side, toward an outer side (or toward an outer peripheral side) compared to the front side and provide it to the first and second multi-channel lenses LS1 and LS2 disposed on the front surfaces thereof, respectively. In particular, the first and second lens frames OS1 and OS2 may refract the image display light incident on the rear surfaces thereof toward the outer side (or toward the outer peripheral side) and provide it to the rear surfaces of the first and second multi-channel lenses LS1 and LS2, respectively.

The first and second multi-channel lenses LS1 and LS2 may form a path for light emitted through the first and second lens frames OS1 and OS2, so that the image display light is visible to the user's eyes on the front side.

The first and second multi-channel lenses LS1 and LS2 may provide a plurality of channels (or paths) through which the image display light emitted from the display panel DP passes. The plurality of channels may provide the image display light emitted from the display panel DP to the user through different paths. The image display light emitted through the first and second lens frames OS1 and OS2 may be incident on the respective channels, and the image magnified through the respective channels may be focused on the user's eyes.

The first and second multi-channel lenses LS1 and LS2 may be respectively arranged on the front surfaces the first and second lens frames OS1 and OS2 to correspond to the positions of the user's left eye and right eye. The first and second multi-channel lenses LS1 and LS2 may be accommodated in the main frame MF.

The first and second multi-channel lenses LS1 and LS2 may refract and/or reflect the image display light emitted through the first and second lens frames OS1 and OS2 at least once to form a path to the user's eyes. At least one infrared light source may be further disposed at the main frame MF, or on one side of each of the first and second multi-channel lenses LS1 and LS2 facing the user's eyes.

The cover frame CF may be disposed on the rear surface DP_RS of the display panel DP to cover the display panel DP and may protect the display panel DP. The cover frame CF may be attached to the main frame MF while covering the display panel DP.

In one or more embodiments, the display device 10_1 may further include a controller for controlling the overall operation of the display device 10_1 including the display panel DP. The controller may control the image display operation of the display panel DP and audio devices. Specifically, the controller performs image processing (e.g., image mapping) according to the magnification ratio and the image display path corresponding to the first and second lens frames OS1 and OS2 and the first and second multi-channel lenses LS1 and LS2, and controls the mapped image to be displayed on the display panel DP. The controller may be implemented as a dedicated processor including an embedded processor and/or a general-purpose processor including a central processing unit (CPU) or an application processor, but is not limited thereto.

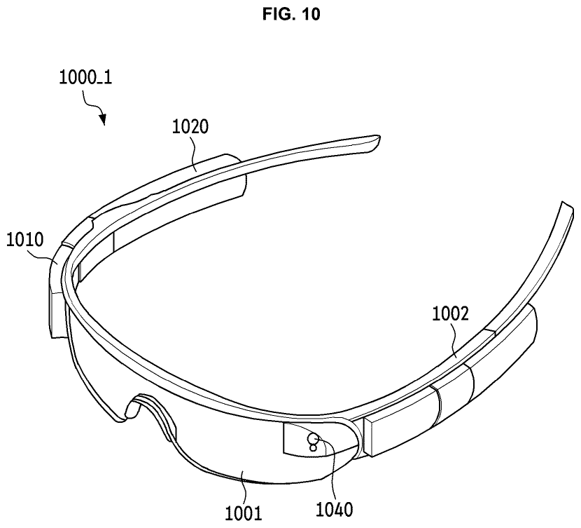

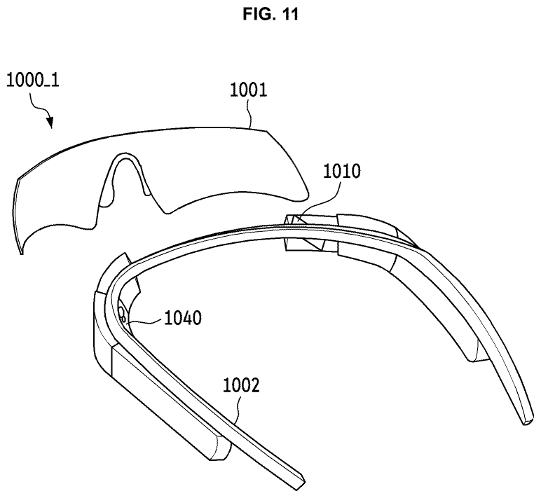

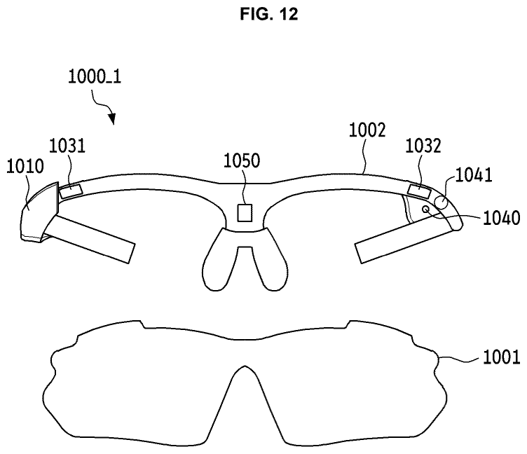

FIG. 10 is a perspective view showing an augmented reality content providing device according to one or more embodiments. FIG. 11 is a rear exploded perspective view of the augmented reality content providing device of FIG. 10. FIG. 12 is a front exploded perspective view of the augmented reality content providing device of FIG. 10.

Referring to FIGS. 10-12, an augmented reality content providing device 1000_1 may include a support frame 1002 supporting at least one transparent lens 1001, at least one image display module 1010, a surrounding environment detector 1040, and a control module 1020.

The support frame 1002 may be formed in the form of glasses including a spectacle frame supporting the edge of at least one transparent lens 1001 and spectacle frame legs. The shape of the support frame 1002 is not limited to a glasses type, and may be formed in a goggle type including the transparent lens 1001, or a head mount type.

The transparent lens 1001 may include left and right parts formed integrally, or first and second transparent lenses formed separately. The transparent lens 1001, which includes the integrated left and right parts or the separated first and second transparent lenses, may be made of glass or plastic that is transparent or translucent. Accordingly, the user can view the image of reality through the transparent lens 1001 that includes the integrated right and left parts or the separated first and second transparent lenses. Here, the transparent lens 1001, that is, the integrated lens or the first and second transparent lenses, may have a refractive power in consideration of the user's eyesight.

The transparent lens 1001 may further include at least one reflective member that reflects the augmented reality content image provided from the at least one image display module 1010 toward the transparent lens 1001 or the user's eyes, and optical members that adjust a focus and a size. One or more reflective member may be built in the transparent lens 1001 to be integrated with the transparent lens 1001, and may be formed as a plurality of refractive lenses or a plurality of prisms with a suitable curvature (e.g., a predetermined curvature).

The at least one image display module 1010 may include a micro LED display device (micro-LED), a nano LED display device (nano-LED), an organic light emitting display device (OLED), an inorganic light emitting display device (inorganic EL), a quantum dot light emitting display device (QED), a cathode ray display (CRT), a liquid crystal display (LCD), and/or the like. The image display module 1010 may substantially include the display device 10 described with reference to FIG. 1 and/or the like.

The surrounding environment detector 1040 is assembled or integrally formed with the support frame 1002, and detects the distance (or depth) to an object on the front side of the support frame 1002, the illuminance, the moving direction of the support frame 1002, the moving distance, the tilt, and/or the like. To this end, the surrounding environment detector 1040 includes a depth sensor 1041 such as an infrared sensor or a LIDAR sensor, and an image sensor 1050 such as a camera. Further, the surrounding environment detector 1040 may further include at least one motion sensor selected from among an illumination sensor, a human body detection sensor, a gyro sensor, a tilt sensor, and an acceleration sensor. Further, the surrounding environment detector 1040 may further include first and second biometric sensors 1031 and 1032 for detecting movement information of the user's eyes or pupils.

The surrounding environment detector 1040 may transmit sensing signals generated by the depth sensor 1041 and at least one motion sensor to the control module 1020 in real time. Further, the image sensor 1050 may transmit image data in units of at least one frame generated in real time to the control module 1020. The first and second biometric sensors 1031 and 1032 of the surrounding environment detector 1040 may transmit the detected pupil detection signals to the control module 1020.

The control module 1020 may be assembled to at least one side of the support frame 1002 together with the at least one image display module 1010 or may be formed integrally with the support frame 1002. The control module 1020 supplies augmented reality content data to the at least one image display module 1010 so that the at least one image display module 1010 displays an augmented reality content, e.g., an augmented reality content image. At the same time, the control module 1020 may receive sensing signals, image data, and pupil detection signals from the surrounding environment detector 1040 in real time.

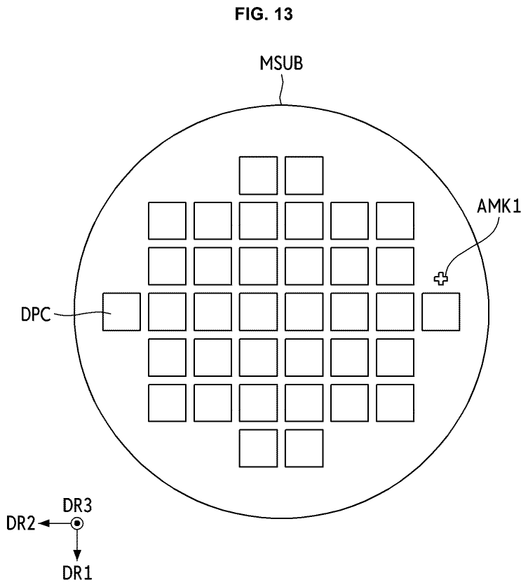

FIG. 13 is a plan view showing a mother semiconductor substrate including a display cell according to one or more embodiments.

Referring to FIG. 13 in addition to FIGS. 7 and 8, a mother semiconductor substrate MSUB may be composed of a semiconductor wafer. The mother semiconductor substrate MSUB may contain a group IV material and/or a group III-V compound. In one or more embodiments, the mother semiconductor substrate MSUB may be composed of a single-crystal wafer. For example, the mother semiconductor substrate MSUB may be a silicon substrate, a germanium substrate, and/or a silicon-germanium substrate.

However, the mother semiconductor substrate MSUB is not limited to the single-crystal wafer, and may be any of various types of wafers such as an epi or epitaxial wafer, a polished wafer, an annealed wafer, and/or a silicon on insulator (SOI) wafer. An epitaxial wafer refers to a wafer in which a crystalline material is grown on a single-crystal silicon substrate.

The mother semiconductor substrate MSUB may include a plurality of display cells DPC. Each of the plurality of display cells DPC may be a preprocessing component that constitutes a part of the display panel 100 described with reference to FIG. 1 and/or the like. For example, the mother semiconductor substrate MSUB may constitute the semiconductor substrate SSUB of the display panel 100, and the plurality of display cells DPC may constitute the semiconductor backplane SBP, the display element layer EML, and the encapsulation layer TFE of the display panel 100.

The plurality of display cells DPC may be formed using semiconductor equipment or through a semiconductor process, but are not limited thereto. After forming the plurality of display cells DPC on the mother semiconductor substrate MSUB, the display panel 100 may be formed by performing cell cutting for each display cell DPC.

In one or more embodiments, each of the plurality of display cells DPC may include a plurality of pixels PX. Each of the plurality of pixels PX included in each of the plurality of display cells DPC may include a plurality of light emitting elements, and the light emitting stack IL (see FIG. 7) or light emitting layer 172 (see FIG. 8) included in the light emitting element may be formed through a deposition process.

The light emitting stack IL may be entirely disposed across the plurality of pixels PX, as shown in FIG. 7, and the light emitting layers 172 may be individually disposed in the emission areas EA1, EA2, and EA3, as shown in FIG. 8. Regardless of the embodiments of FIGS. 7 and 8, a more precise deposition mask is required to form the light emitting stack IL or the light emitting layer 172 in the high-resolution display device 10, and such a deposition mask for forming the high-resolution display device 10 will be described below.

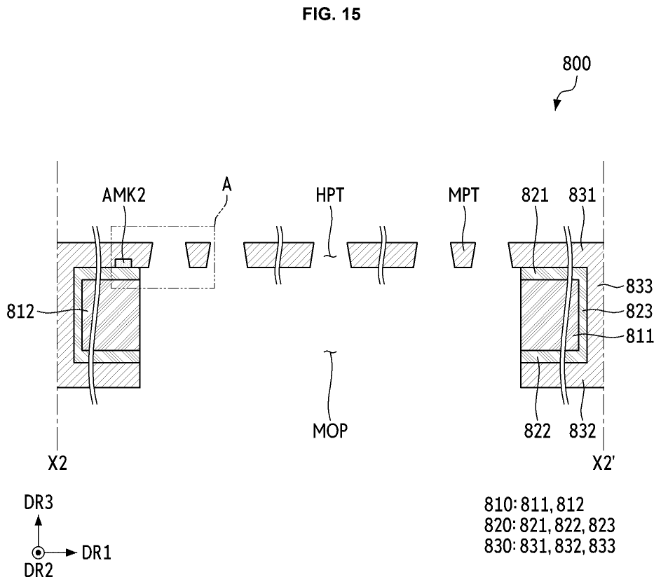

FIG. 14 is a plan view showing a deposition mask according to one or more embodiments. FIG. 15 is a cross-sectional view taken along the line X2-X2′ of FIG. 14.

Referring to FIGS. 14 and 15 in addition to FIG. 13, the deposition mask 800 according to one or more embodiments may be a deposition mask for use in manufacturing an ultra-high resolution display. For example, the deposition mask 800 according to one or more embodiments may be a deposition mask for use in manufacturing a display included in the head mounted display or augmented reality content providing device described with reference to FIGS. 9-12.

In one or more embodiments, the deposition mask 800 may be used to perform a pixel deposition process on a silicon wafer rather than a large-area substrate used in a conventional display. For example, in the case of a display included in an extended reality device, because a screen is positioned directly in front of the user's eyes, it may have a small screen rather than a large one. In addition, because the display is positioned close to the user's eyes, ultra-high resolution may be required. For example, the required resolution of the display included in the extended reality device may be approximately 1000 PPI or higher, and, desirably, an ultra-high resolution of 3000 PPI or higher may be required. The deposition mask 800 according to one or more embodiments may be a mask for use in manufacturing such an ultra-high resolution display. In one or more embodiments, the deposition mask 800 may be a fine silicon mask (FSM).

The deposition mask 800 may include a mask substrate 810 and a plurality of mask cells MSC.

The mask substrate 810 may be composed of a semiconductor wafer. The mask substrate 810 may contain a group IV material and/or a group III-V compound. In one or more embodiments, the mask substrate 810 may be composed of a single-crystal wafer. For example, the mask substrate 810 may be a silicon substrate, a germanium substrate, or a silicon-germanium substrate.

However, the mask substrate 810 is not limited to the single-crystal wafer, and may be any of various types of wafers such as an epi or epitaxial wafer, a polished wafer, an annealed wafer, and an SOI (silicon on insulator) wafer. An epitaxial wafer is a wafer in which a crystalline material is grown on a single-crystal silicon substrate.

The mask substrate 810 may have a shape corresponding to a silicon wafer of an ultra-high resolution display. For example, the mask substrate 810 may have the same size or shape as the mother semiconductor substrate MSUB as a substrate of an ultra-high resolution display.

The plurality of mask cells MSC may be arranged to correspond to the plurality of display cells DPC of the mother semiconductor substrate MSUB. For example, in a deposition process for manufacturing the display device 10 (see FIG. 1), the deposition mask 800 may be positioned on the mother semiconductor substrate MSUB. At this time, the plurality of mask cells MSC may overlap the plurality of display cells DPC of the mother semiconductor substrate MSUB, respectively.

To align the plurality of mask cells MSC to overlap the plurality of display cells DPC, the mother semiconductor substrate MSUB may include a first alignment mark AMK1, and the deposition mask 800 may include a second alignment mark AMK2. The first alignment mark AMK1 and the second alignment mark AMK2 may each contain metal, but are not limited thereto.

The plurality of mask cells MSC may be formed using semiconductor equipment or through a semiconductor process, but are not limited thereto. By forming the plurality of mask cells MSC on the mask substrate 810 composed of a semiconductor wafer using semiconductor equipment or through a semiconductor process, the deposition mask 800 according to the present embodiment may be provided with an ultra-high resolution pattern. An ultra-high resolution display may be manufactured using this ultra-high resolution pattern.

The deposition mask 800 may include the mask substrate 810, a first coating film 820, the second alignment mark AMK2, and a second coating film 830.

A description of the mask substrate 810 will be omitted here as it has been already described above.

The first coating film 820 may be disposed on the mask substrate 810. The first coating film 820 may be an inorganic film containing an inorganic material. For example, the first coating film 820 may contain silicon oxide (SiOₓ).

The second alignment mark AMK2 may be disposed on the first coating film 820. However, the present disclosure is not limited thereto, and the second alignment mark AMK2 may be disposed on the mask substrate 810 or on the second coating film 830.

The second coating film 830 may be disposed on the second alignment mark AMK2 and the first coating film 820. The second coating film 830 may be an inorganic film containing an inorganic material. For example, the second coating film 830 may contain silicon nitride (SiNₓ).

In one or more embodiments, the second coating film 830 may contain low stress nitride (LSN). When the second coating film 830 contains the low stress nitride, the second coating film 830 may be formed by a low pressure chemical vapor deposition (LPCVD) process, but is not limited thereto. Because the second coating film 830 contains the low stress nitride, even if a plurality of mask patterns MPT and a plurality of hole patterns HPT to be described later are formed, the durability of the deposition mask 800 may be improved by a low stress.

In one or more embodiments, the first coating film 820 and the second coating film 830 may cover the top surface, bottom surface, and side surface of the mask substrate 810. For example, the first coating film 820 may include a first upper coating film 821 disposed on the top surface of the mask substrate 810, a first lower coating film 822 disposed on the bottom surface of the mask substrate 810, and a first side coating film 823 disposed on the side surface of the mask substrate 810. The second coating film 830 may include a second upper coating film 831 disposed on the top surface of the mask substrate 810, a second lower coating film 832 disposed on the bottom surface of the mask substrate 810, and a second side coating film 833 disposed on the side surface of the mask substrate 810. The second upper coating film 831 may be disposed on the first upper coating film 821, the second lower coating film 832 may be disposed on the first lower coating film 822, and the second side coating film 833 may be disposed on the first side coating film 823.

However, the present disclosure is not limited thereto, and the first coating film 820 may include only the first upper coating film 821, and the second coating film 830 may include only the second upper coating film 831.

The deposition mask 800 may include the plurality of mask patterns MPT and the plurality of hole patterns HPT disposed in the second coating film 830. The plurality of mask patterns MPT and the plurality of hole patterns HPT may be disposed in the second upper coating film 831 of the second coating film 830.

The plurality of mask patterns MPT and the plurality of hole patterns HPT may be alternately arranged. For example, the plurality of mask patterns MPT and the plurality of hole patterns HPT may be alternately arranged along the first direction DR1 and/or the second direction DR2.

Although the plurality of mask patterns MPT are spaced (e.g. spaced apart) from each other in the first direction DR1 or the second direction DR2 in cross-sectional view, they may be a single pattern connected to each other in a plan view. In the following description, the mask pattern MPT may refer to the whole of the plurality of patterns positioned on the mask substrate 810 as a single component, or may refer to each of the plurality of patterns. That is, the plurality of mask patterns MPT may be used interchangeably to refer to the whole group of the plurality of patterns as a single component or to refer to each of the plurality of patterns.

The deposition mask 800 may include a mask opening MOP penetrating the mask substrate 810, the first coating film 820, and the second coating film 830. For example, the mask opening MOP may penetrate the second lower coating film 832, the first lower coating film 822, the mask substrate 810, and the first upper coating film 821. In cross-sectional view, the mask substrate 810 may be divided into a first portion 811 and a second portion 812 by the mask opening MOP penetrating the mask substrate 810.

In one or more embodiments, when the first coating film 820 includes only the first upper coating film 821 and the second coating film 830 includes only the second upper coating film 831, the mask opening MOP may penetrate the mask substrate 810 and the first upper coating film 821.

Although the inner surface of the mask opening MOP is depicted as a vertical plane in the drawing, it is not limited thereto. For example, the inner surface of the mask opening MOP may be sloped or curved due to the isotropy of a wet etching process.

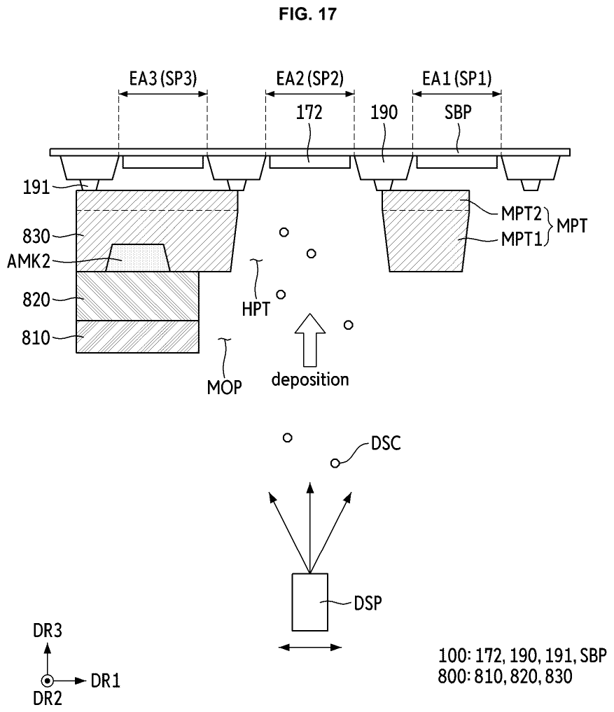

The mask opening MOP may communicate with the hole pattern HPT. Accordingly, the mask opening MOP and the hole pattern HPT may provide a passage through which a deposition source DSC (see FIG. 17) can move. The mask substrate 810 and the mask pattern MPT may block the deposition source DSC (see FIG. 17) in an area other than the passage formed by the mask opening MOP and the hole pattern HPT being in communication with each other.

In one or more embodiments, the mask opening MOP may be plural in number, corresponding to the mask cells MSC. For example, a plurality of mask openings MOP may be respectively disposed for the plurality of mask cells MSC. However, the present disclosure is not limited thereto, and in other embodiments, the mask opening MOP may be formed as one across the plurality of mask cells MSC.

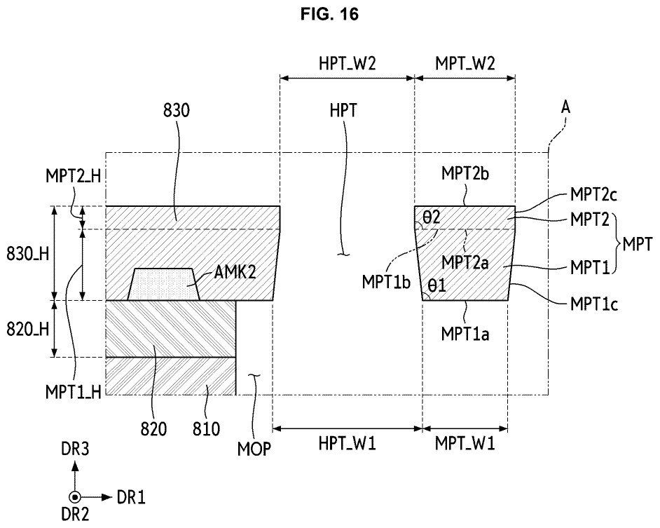

FIG. 16 is an enlarged view of an area A of FIG. 15.

Referring to FIG. 16 in addition to FIG. 15, the mask pattern MPT may have a reverse-tapered shape. For example, a lower width MPT_W1 of the mask pattern MPT may be less than an upper width MPT_W2 thereof.

The hole pattern HPT may have a normal-tapered shape. For example, an upper width HPT_W2 of the hole pattern HPT may be less than a lower width HPT_W1 of the hole pattern HPT.

The mask pattern MPT may include a first portion MPT1 and a second portion MPT2 positioned on the first portion MPT1. In the present disclosure, although the first portion MPT1 and the second portion MPT2 are described separately for convenience of explanation, the first portion MPT1 and the second portion MPT2 may be physically connected to each other as a single component.

The first portion MPT1 may include a first surface MPT1a, a second surface MPT1b located opposite the first surface MPT1a, and a first side surface MPT1c located between the first surface MPT1a and the second surface MPT1b. The first surface MPT1a of the first portion MPT1 is a surface facing the mask substrate 810, the second surface MPT1b of the first portion MPT1 is a surface facing the second portion MPT2, and the first side surface MPT1c of the first portion MPT1 is a surface connecting the first surface MPT1a to the second surface MPT1b and is in contact with the hole pattern HPT.

The first portion MPT1 may have a reverse-tapered shape. For example, the width of the first surface MPT1a of the first portion MPT1 may be less than the width of the second surface MPT1b of the first portion MPT1. That is, the width of the first portion MPT1 may become narrower as it goes from the second surface MPT1b of the first portion MPT1 toward the first surface MPT1a of the first portion MPT1. The first side surface MPT1c of the first portion MPT1 may be an inclined surface that is inclined in an inward direction of the first portion MPT1 as it goes from the second surface MPT1b of the first portion MPT1 toward the first surface MPT1a of the first portion MPT1. A first angle θ1, which is an internal angle formed by the first surface MPT1a of the first portion MPT1 and the first side surface MPT1c of the first portion MPT1, may be an obtuse angle. In one or more embodiments, the first angle θ1 may be approximately greater than 90 degrees and less than 100 degrees, and, desirably, the first angle θ1 may be approximately greater than or equal to 93 degrees and less than or equal to 97 degrees, but is not limited thereto.

The second portion MPT2 may be positioned on the first portion MPT1. The second portion MPT2 may be located opposite the mask opening MOP with the first portion MPT1 therebetween.

The second portion MPT2 may include a first surface MPT2a, a second surface MPT2b located opposite the first surface MPT2a, and a first side surface MPT2c located between the first surface MPT2a and the second surface MPT2b. The first surface MPT2a of the second portion MPT2 is a surface facing the first portion MPT1, the second surface MPT2b of the second portion MPT2 is a surface opposite to the first surface MPT2a, and the first side surface MPT2c of the second portion MPT2 is a surface connecting the first surface MPT2a of the second portion MPT2 to the second surface MPT2b of the second portion MPT2 and is in contact with the hole pattern HPT.

In one or more embodiments, the second portion MPT2 may have a reverse-tapered shape. For example, the width of the first surface MPT2a of the second portion MPT2 may be less than the width of the second surface MPT2b of the second portion MPT2. That is, the width of the second portion MPT2 may become narrower as it goes from the second surface MPT2b of the second portion MPT2 toward the first surface MPT2a of the second portion MPT2. The first side surface MPT2c of the second portion MPT2 may be an inclined surface that is inclined in an inward direction of the second portion MPT2 as it goes from the second surface MPT2b of the second portion MPT2 toward the first surface MPT2a of the second portion MPT2. A second angle θ2, which is an internal angle formed by the first surface MPT2a of the second portion MPT2 and the first side surface MPT2c of the second portion MPT2, may be an obtuse angle. In one or more embodiments, the second angle θ2 may be approximately greater than 90 degrees and less than or equal to 93 degrees, but is not limited thereto.

In one or more embodiments, the second portion MPT2 may be of a vertical shape. For example, the width of the first surface MPT2a of the second portion MPT2 may be the same as the width of the second surface MPT2b of the second portion MPT2. In this case, the first side surface MTP2c of the second portion MPT2 may be a vertical plane, and the second angle θ2, which is the internal angle formed by the first surface MPT2a of the second portion MPT2 and the first side surface MPT2c of the second portion MPT2, may be a right angle.

In the deposition mask 800 according to the present embodiment, the inclination angle of the first side surface MPT1c of the first portion MPT1 and the inclination angle of the first side surface MPT2c of the second portion MPT2 may be different. For example, the second angle θ2, which is the inclination angle of the first side surface MPT2c of the second portion MPT2, may be smaller than the first angle θ1, which is the inclination angle of the first side surface MPT1c of the first portion MPT1.

In one or more embodiments, a thickness 820_H of the first coating film 820 and a thickness 830_H of the second coating film 830 may be in the range of approximately 0.4 μm to 1.4 μm, but are not limited thereto. A height MPT1_H of the first portion MPT1 may be greater than the height MPT2_H of the second portion MPT2. For example, the height MPT1_H of the first portion MPT1 may be approximately 0.3 μm to 1 μm, and the height MPT2_H of the second portion MPT2 may be approximately 0.05 μm to 0.5 μm, but are not limited thereto.

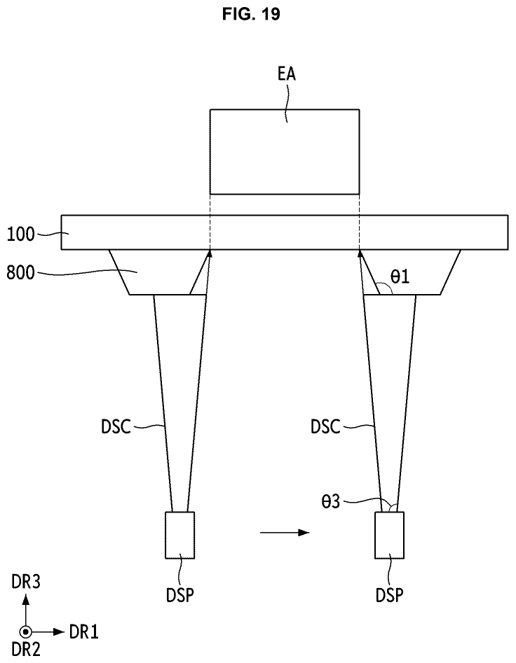

As the deposition mask 800 according to the present embodiment includes the mask pattern MPT of the reverse-tapered shape and the hole pattern HPT of the normal-tapered shape, the efficiency of the deposition process may be improved. This will be described later with reference to FIGS. 17 and 19.

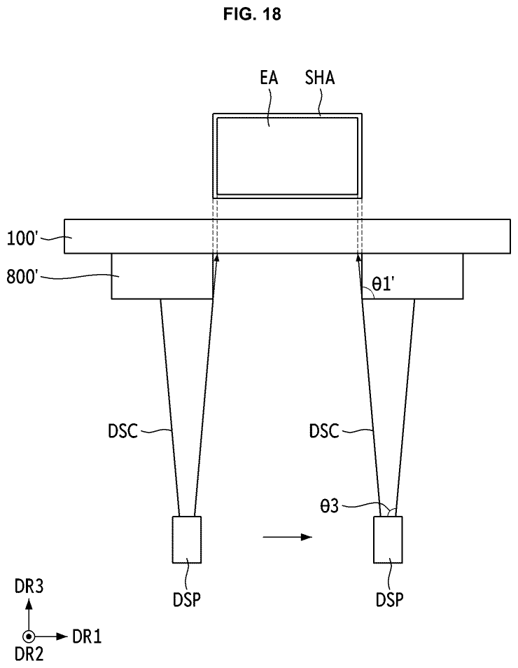

FIG. 17 is a cross-sectional view showing a process of manufacturing a display device using a deposition mask according to one or more embodiments. FIG. 18 is a schematic diagram showing an emission area and a shadow area formed when manufacturing a display device using a deposition mask according to a comparative example. FIG. 19 is a schematic diagram showing an emission area formed when manufacturing a display device using a deposition mask according to one or more embodiments.

Referring to FIGS. 17-19, the deposition mask 800 may be used to form the light emitting layer 172 in each of the sub-pixels SP1, SP2, and SP3 of the display panel 100. The display panel 100 may be disposed such that the semiconductor backplane SBP thereof is located far from a deposition source supply DSP. For example, the semiconductor backplane SBP may be disposed such that it faces upwards, and the sub-pixels SP1, SP2, and SP3 may be disposed such that they face downwards.

In the case where the sub-pixels SP1, SP2, and SP3 are pixels that implement different colors, the materials of the light emitting sources included in the light emitting layers 172 of the respective sub-pixels SP1, SP2, and SP3 may be different. That is, the deposition sources DSC for forming the light emitting layers 172 of the respective sub-pixels SP1, SP2, and SP3 may be different.

Therefore, when forming the light emitting layer 172 in one of the sub-pixels SP1, SP2, and SP3, the sub-pixel SP1, SP2, or SP3 in which the light emitting layer 172 is to be formed may be disposed to overlap the hole pattern HPT, and the rest sub-pixels SP1, SP2, or SP3 may be disposed to overlap the mask pattern MPT.

Accordingly, the deposition source DSC jetted from the deposition source supply DSP may pass through the mask opening MOP and the hole pattern HPT only in the sub-pixel SP1, SP2, or SP3 in which the light emitting layer 172 is formed and may be placed on the semiconductor backplane SBP of the display panel 100.

The deposition mask 800 may be placed on the spacer 191 of the display panel 100. For example, the second portion MPT2 of the mask pattern MPT may be placed on the spacer 191. The second portion MPT2 of the mask pattern MPT may be in direct contact with the spacer 191.

As illustrated in FIG. 18, a first angle θ1′ between a side surface and a bottom surface of the mask pattern MPT in a deposition mask 800′ according to the comparative example may be 90 degrees or less. For example, the mask pattern MPT of the deposition mask 800′ according to the comparative example may have a normal-tapered shape whose width becomes narrower as it goes from the bottom surface toward the top surface thereof, or may have a vertical shape.

In this case, the first angle θ1′ of the deposition mask 800′ according to the comparative example may be smaller than a third angle θ3 at which the deposition source DSC is jetted. Therefore, some of the deposition source DSC may be accumulated on the side surface and the bottom surface of the mask pattern MPT of the deposition mask 800′ according to the comparative example, resulting in a material loss. Accordingly, a shadow area SHA may be formed around the emission area EA formed in the display panel 100′. The shadow area SHA means an area where the thickness of the deposition source DSC is less than or equal to a certain thickness (for example, a thickness equal to 90% of the thickness of the deposition source DSC accumulated in the emission area EA).

As illustrated in FIG. 19, the first angle θ1 between a side surface and a bottom surfaces of the mask pattern MPT in the deposition mask 800 according to one or more embodiments may be greater than 90 degrees. For example, the mask pattern MPT of the deposition mask 800 according to one or more embodiments may have a reverse-tapered shape whose width becomes wider as it goes from the bottom surface toward the top surface thereof.

In this case, the first angle θ1 in the deposition mask 800 according to one or more embodiments may be greater than the third angle θ3, which is the angle at which the deposition source DSC is jetted. Accordingly, no shadow area SHA is formed around the emission area EA formed in the display panel 100, and the size of the emission area EA may increase as compared to that of the comparative example. As a result, a material loss may be reduced or minimized, and the size of the emission area EA may increase, resulting in improvement in the efficiency of the deposition process.

Hereinafter, other embodiments of the deposition mask according to one or more embodiments will be described. In the following embodiments, description of the same components as those of the above-described embodiment, which are denoted by like reference numerals, will be omitted or simplified, and differences will be mainly described.

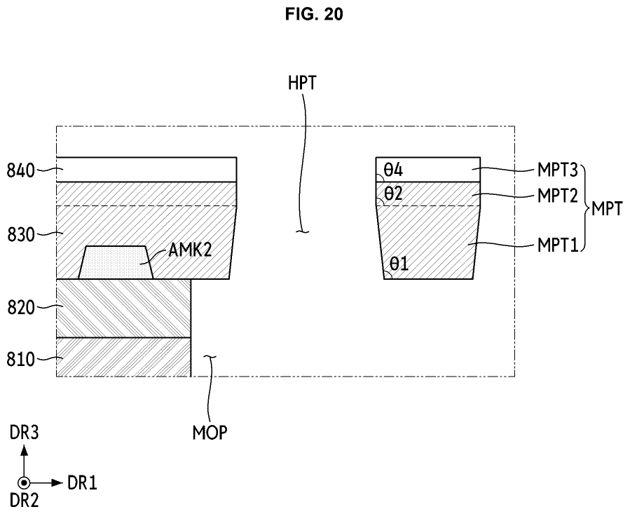

FIG. 20 is a plan view showing a deposition mask according to one or more other embodiments.

Referring to FIG. 20, the deposition mask 800 according to the present embodiment is different from the deposition mask 800 according to the embodiment described with reference to FIG. 16 and the like in that it further includes a third coating film 840 and a third portion MPT3.

To elaborate, the deposition mask 800 according to the present embodiment may further include the third coating film 840.

The third coating film 840 may be disposed on the second coating film 830. In one or more embodiments, the third coating film 840 may be an inorganic film containing an inorganic material. For example, the third coating film 840 may contain silicon oxide (SiOₓ). In one or more other embodiments, the third coating film 840 may be a metal layer containing metal.

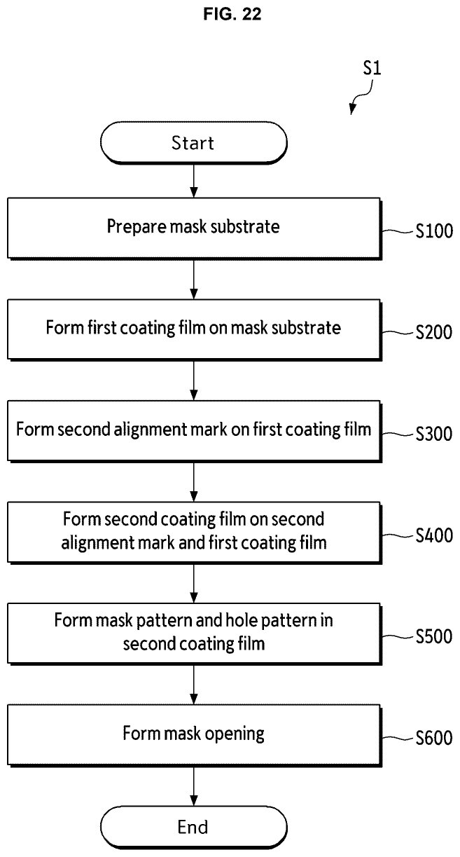

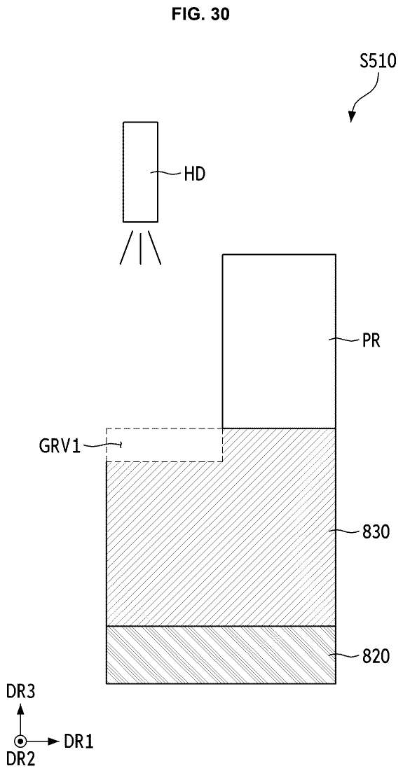

The third coating film 840 may be formed as a result of a residue of a hard mask when the hard mask is placed between the second coating film 830 and a photoresist PR (see FIG. 30) in step S500 (see FIG. 22) of forming a mask pattern and a hole pattern in a second coating film in a method S1 (see FIG. 22) of manufacturing a deposition mask to be described later.

The mask pattern MPT may further include the third portion MPT3. In this specification, although the first portion MPT1, the second portion MPT2, and the third portion MPT3 are described separately for convenience of explanation, the first portion MPT1, the second portion MPT2, and the third portion MPT3 may be physically connected to each other as a single component.

The third portion MPT3 may be disposed on the second portion MPT2. The third portion MPT3 may be located opposite the first portion MPT1 with the second portion MPT2 therebetween. The third portion MPT3 may be a part of the third coating film 840.

In one or more embodiments, the third portion MPT3 may have a reverse-tapered shape. For example, the width of the bottom surface of the third portion MPT3 may be less than the width of the top surface of the third portion MPT3. That is, the width of the third portion MPT3 may become narrower as it goes from the top surface toward the bottom surface of the third portion MPT3. The side surface of the third portion MPT3 may be an inclined surface that is inclined inwardly as it goes from the top surface toward the bottom surface of the third portion MPT3. A fourth angle θ4, which is an internal angle formed by the bottom surface and the side surface of the third portion MPT3, may be an obtuse angle. In one or more embodiments, the fourth angle θ4 may be approximately greater than 90 degrees and less than or equal to 93 degrees, but is not limited thereto.

In another embodiment, the third portion MPT3 may have a vertical shape. For example, the width of the bottom surface of the third portion MPT3 may be the same as the width of the top surface thereof. In this case, the side surface of the third portion MPT3 may be a vertical plane, and the fourth angle θ4, which is the internal angle formed by the bottom surface and the side surface of the third portion MPT3, may be a right angle.

In the deposition mask 800 according to the present embodiment, the side inclination angle of the first portion MPT1, the side inclination angle of the second portion MPT2, and the side inclination angle of the third portion MPT3 may be different from each other. For example, the fourth angle θ4, which is the side inclination angle of the third portion MPT3, may be smaller than the second angle θ2, which is the side inclination angle of the second portion MPT2, and the first angle θ1, which is the side inclination angle of the first portion MPT1.

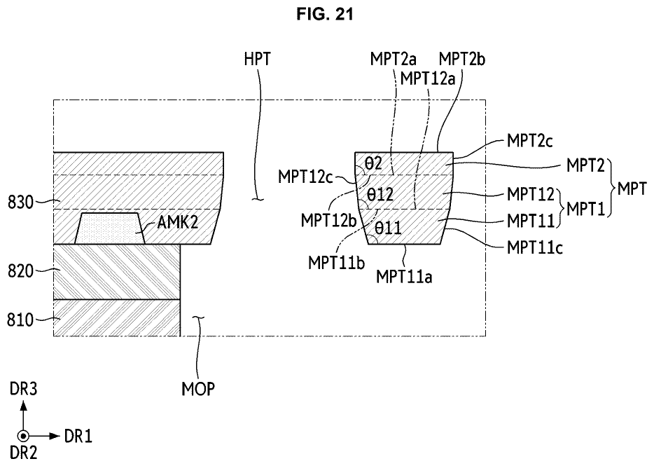

FIG. 21 is a cross-sectional view showing a deposition mask according to still another embodiment.

Referring to FIG. 21, the deposition mask 800 according to the present embodiment is different from the deposition mask 800 according to the embodiment described with reference to FIG. 16 and/or the like in that the first portion MPT1 includes a first sub-portion MPT11 and a second sub-portion MPT12.

To elaborate, the first portion MPT1 of the mask pattern MPT may include the first sub-portion MPT11 and the second sub-portion MPT12. In this specification, although the first sub-portion MPT11 and the second sub-portion MPT12 of the first portion MPT1, and the second portion MPT2 are described separately for convenience of explanation, the first sub-portion MPT11 and the second sub-portion MPT12 of the first portion MPT1, and the second portion MPT2 may be physically connected to each other as a single component.

The first sub-portion MPT11 may be positioned under the second sub-portion MPT12. For example, the first sub-portion MPT11 may be located opposite the second portion MPT2 with the second sub-portion MPT12 therebetween.

The first sub-portion MPT11 may include a first surface MPT11a, a second surface MPT11b located opposite the first surface MPT11a, and a first side surface MPT11c located between the first surface MPT11a and the second surface MPT11b. The first surface MPT11a of the first sub-portion MPT11 is a surface facing the mask substrate 810, the second surface MPT11b of the first sub-portion MPT11 is a surface facing the second sub-portion MPT12, and the first side surface MPT11c of the first sub-portion MPT11 is a surface connecting the first surface MPT11a to the second surface MPT11b and is in contact with the hole pattern HPT.

The first sub-portion MPT11 may have a reverse-tapered shape. For example, the width of the first surface MPT11a of the first sub-portion MPT11 may be less than the width of the second surface MPT11b of the first sub-portion MPT11. That is, the width of the first sub-portion MPT11 may become narrower as it goes from the second surface MPT11b of the first sub-portion MPT11 toward the first surface MPT11a thereof. The first side surface MPT11c of the first sub-portion MPT11 may be an inclined surface that is inclined in an inward direction of the first sub-portion MPT11 as it goes from the second surface MPT11b of the first sub-portion MPT11 toward the first surface MPT11a of the first sub-portion MPT11. A first-first angle θ11, which is an internal angle formed by the first surface MPT11a of the first sub-portion MPT11 and the first side surface MPT11c of the first sub-portion MPT11, may be an obtuse angle. In one or more embodiments, the first-first angle θ11 may be approximately greater than 90 degrees and less than 100 degrees, and, desirably, the first-first angle θ11 may be approximately greater than or equal to 95 degrees and less than or equal to 97 degrees, but is not limited thereto.

The second sub-portion MPT12 may be positioned above the first sub-portion MPT11. For example, the second sub-portion MPT12 may be positioned between the first sub-portion MPT11 and the second portion MPT2.

The second sub-portion MPT12 may include a first surface MPT12a, a second surface MPT12b located opposite the first surface MPT12a, and a first side surface MPT12c located between the first surface MPT12a and the second surface MPT12b. The first surface MPT12a of the second sub-portion MPT12 is a surface facing the first sub-portion MPT11, the second surface MPT12b of the second sub-portion MPT12 is a surface facing the second portion MPT2, and the first side surface MPT12c of the second sub-portion MPT12 is a surface connecting the first surface MPT12a to the second surface MPT12b and is in contact with the hole pattern HPT.

The second sub-portion MPT12 may have a reverse-tapered shape. For example, the width of the first surface MPT12a of the second sub-portion MPT12 may be less than the width of the second surface MPT12b of the second sub-portion MPT12. That is, the width of the second sub-portion MPT12 may become narrower as it goes from the second surface MPT12b of the second sub-portion MPT12 toward the first surface MPT12a of the second sub-portion MPT12. The first side surface MPT12c of the second sub-portion MPT12 may be an inclined surface that is inclined in an inward direction of the second sub-portion MPT12 as it goes from the second surface MPT12b of the second sub-portion MPT12 toward the first surface MPT12a of the second sub-portion MPT12. A first-second angle θ12, which is an internal angle formed by the first surface MPT12a of the second sub-portion MPT12 and the first side surface MPT12c of the second sub-portion MPT12, may be an obtuse angle. In one or more embodiments, the first-second angle θ12 may be approximately greater than 90 degrees and less than 100 degrees, and, desirably, the first-second angle θ12 may be approximately greater than or equal to 93 degrees and less than or equal to 95 degrees, but is not limited thereto.

In the deposition mask 800 according to the present embodiment, the inclination angle of the first side surface MPT11c of the first sub-portion MPT11, the inclination angle of the first side surface MPT12c of the second sub-portion MPT12, and the inclination angle of the first side surface MPT2c of the second portion MPT2 may be different from each other. For example, the second angle θ2, which is the inclination angle of the first surface MPT2c of the second portion MPT2, may be smaller than the first-first angle θ11, which is the inclination angle of the first side surface MPT11c of the first sub-portion MPT11, and the first-first angle θ11, which is the inclination angle of the first side surface MPT11c of the first sub-portion MPT11, may be smaller than the first-second angle θ12, which is the inclination angle of the first side surface MPT12c of the second sub-portion MPT12.

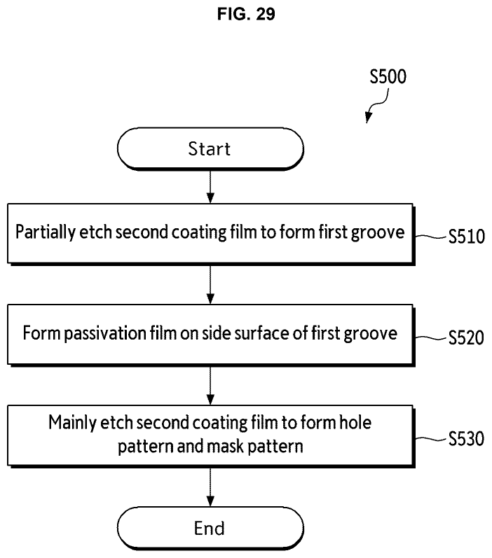

In the present embodiment, although it is illustrated as an example that the first portion MPT1 is divided into two sub-portions, such as the first sub-portion MPT11 and the second sub-portion MPT12, the present disclosure is not limited thereto. For example, the first portion MPT1 may be divided into three or more sub-portions. The number of the sub-portions of the first portion MPT1 may vary depending on the number of repetitions of step S530 (see FIG. 29) of forming a mask pattern and a hole pattern by mainly etching a second coating film in the middle of step S500 (see FIG. 22) of forming the mask pattern and the hole pattern in the second coating film in the method S1 (see FIG. 22) of manufacturing a deposition mask to be described later.

Hereinafter, a method for manufacturing the mask pattern MPT of the deposition mask 800 in a reverse-tapered shape will be described.

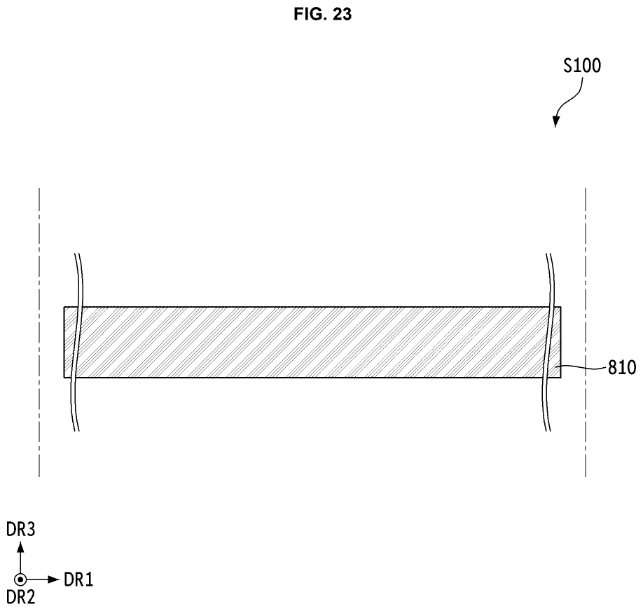

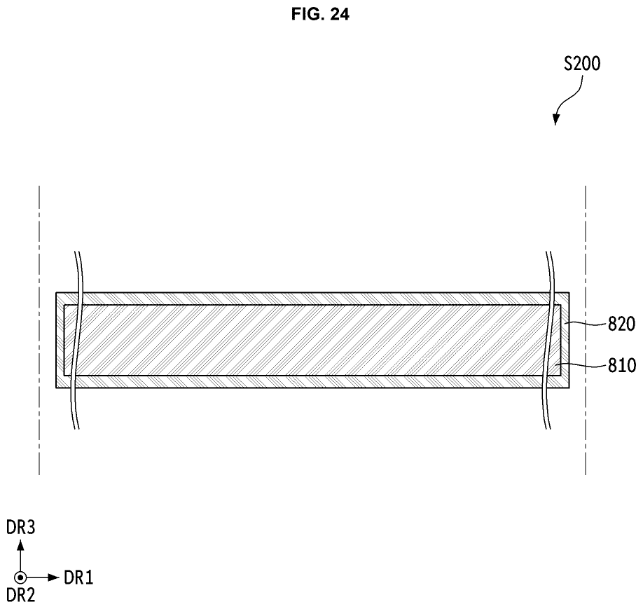

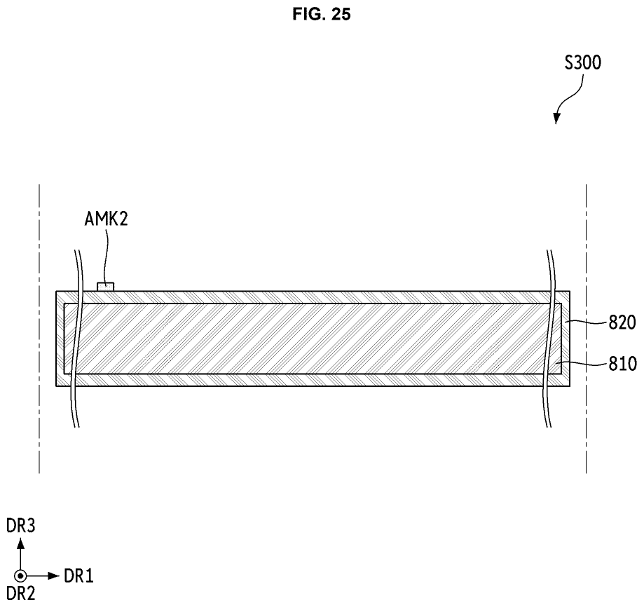

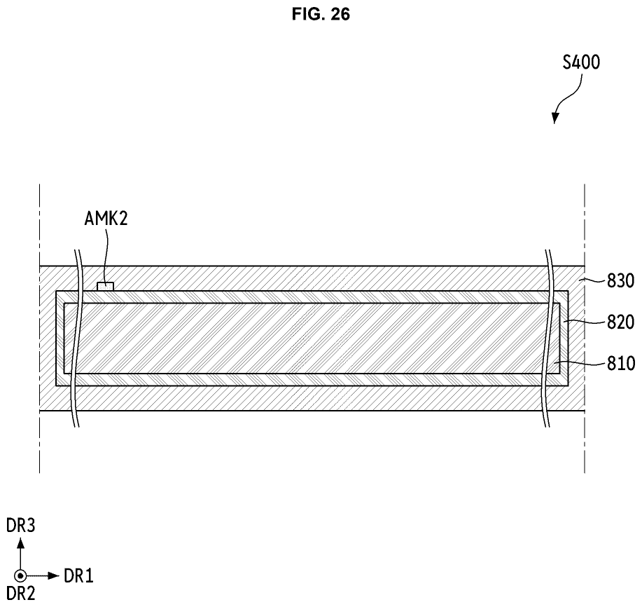

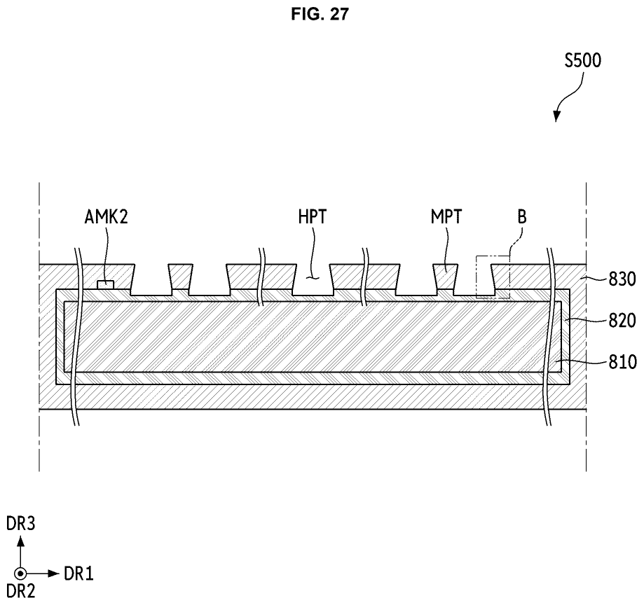

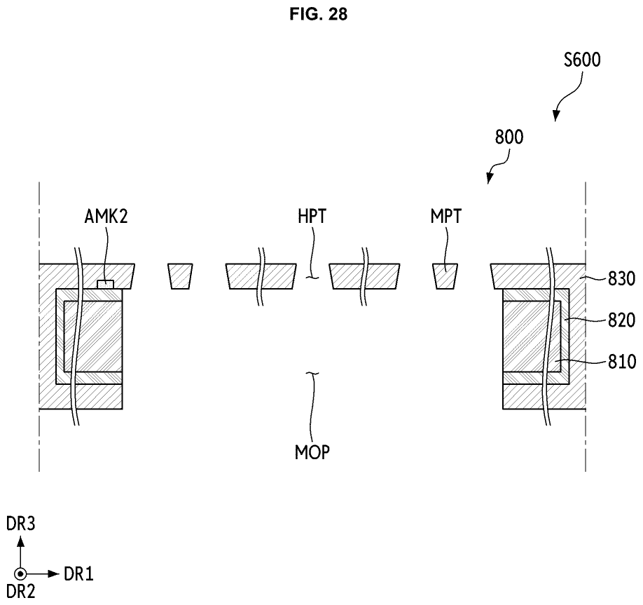

FIG. 22 is a flowchart showing a method of manufacturing a deposition mask according to one or more embodiments. FIG. 23 is a cross-sectional view showing step S100 of FIG. 22. FIG. 24 is a cross-sectional view showing step S200 of FIG. 22. FIG. 25 is a cross-sectional view showing step S300 of FIG. 22. FIG. 26 is a cross-sectional view showing step S400 of FIG. 22. FIG. 27 is a cross-sectional view showing step S500 of FIG. 22. FIG. 28 is a cross-sectional view showing step S600 of FIG. 22.

Referring to FIGS. 22-28 in addition to FIG. 15, the method S1 of manufacturing a deposition mask according to one or more embodiments may include preparing a mask substrate (step S100), forming a first coating film on the mask substrate (step S200), forming a second alignment mark on the first coating film (step S300), forming a second coating film on the second alignment mark and the first coating film (step S400), forming a mask pattern and a hole pattern in the second coating film (step S500), and forming a mask opening (step S600).

Firstly, as illustrated in FIG. 23, in the step S100 of preparing the mask substrate, the mask substrate 810 may be prepared. The mask substrate 810 may be composed of a semiconductor wafer, as described above. A description of the mask substrate 810 will be omitted here as it has been already described above.

Secondly, as illustrated in FIG. 24, in the step S200 of forming the first coating film on the mask substrate, the first coating film 820 may be deposited on the mask substrate 810. The first coating film 820 may cover not only the top surface but also the bottom and side surfaces of the mask substrate 810.

The first coating film 820 may be an inorganic film containing an inorganic material as described above. For example, the first coating film 820 may contain silicon oxide (SiOₓ).

Thirdly, as illustrated in FIG. 25, in the step S300 of forming the second alignment mark on the first coating film, the second alignment mark AMK2 may be patterned on the first coating film 820.

For example, after an alignment mark material layer for forming the second alignment mark AMK2 is formed on the first coating film 820, the alignment mark material layer may be patterned through a photolithography process to form the second alignment mark AMK2. The alignment mark material layer may contain, but is not limited to, metal.

Fourthly, as illustrated in FIG. 26, in the step S400 of forming the second coating film on the second alignment mark and the first coating film, the second coating film 830 may be deposited on the second alignment mark AMK2 and the first coating film 820. The second coating film 830 may cover not only the top surface but also the bottom and side surfaces of the mask substrate 810.

The second coating film 830 may be an inorganic film containing an inorganic material as described above. For example, the second coating film 830 may contain silicon nitride (SiNₓ).

In one or more embodiments, the second coating film 830 may contain low stress nitride (LSN). When the second coating film 830 contains the low stress nitride, the second coating film 830 may be formed by a low pressure chemical vapor deposition (LPCVD) process, but is not limited thereto.

Fifthly, as illustrated in FIG. 27, in the step S500 of forming the mask pattern and the hole pattern in the second coating film, the second coating film 830 may be patterned to form the mask pattern MPT and the hole pattern HPT.

The patterning of the second coating film 830 may be performed by a dry etching process. The step S500 of forming the mask pattern and the hole pattern in the second coating film will be described in further detail later with reference to FIG. 29 and/or the like.

Sixthly, as illustrated in FIG. 28, in the step S600 of forming the mask opening, the portion under the deposition mask 800 may be etched to form the mask opening MOP. For example, as described above with reference to FIG. 15, the mask opening MOP may be formed by etching the second lower coating film 832, the first lower coating film 822, the mask substrate 810, and the first upper coating film 821 (e.g., see FIG. 15).

The mask opening MOP may be formed by a wet etching process. Therefore, although the inner surface of the mask opening MOP is depicted as being a vertical plane in the drawing, the shape of the opening mask MOP is not limited thereto. For example, the inner surface of the mask opening MOP may be sloped or curved due to the isotropy of the wet etching.

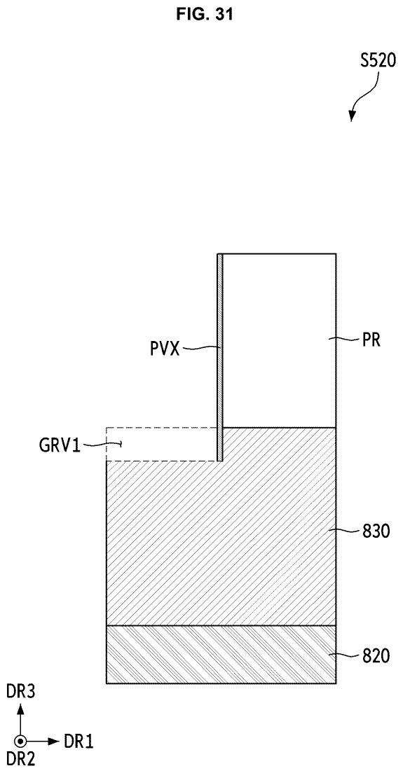

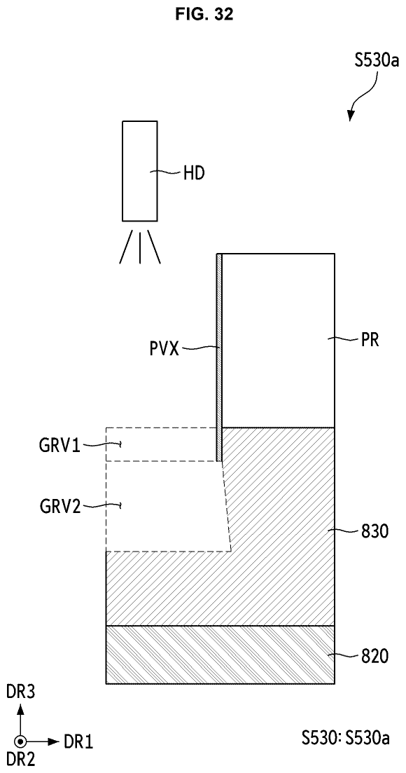

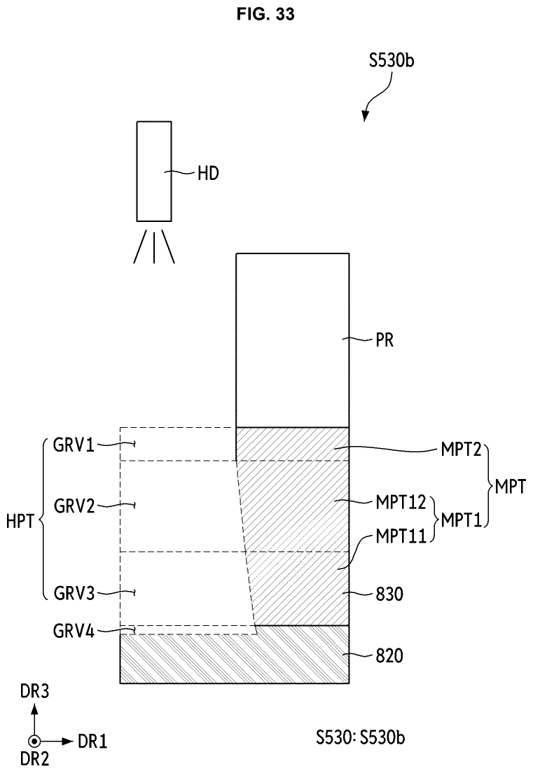

FIG. 29 is a flowchart showing detailed sub-steps of the step S500 of FIG. 22. FIG. 30 is a cross-sectional view showing step S510 of FIG. 29. FIG. 31 is a cross-sectional view showing step S520 of FIG. 29. FIGS. 32 and 33 are cross-sectional views showing step S530 of FIG. 29. FIGS. 30-33 illustrate only a portion of the deposition mask 800.

Referring to FIGS. 29-33 in addition to FIG. 22, the step S500 of forming the mask pattern and the hole pattern in the second coating film may include partially etching the second coating film to form a first groove (step S510), forming a passivation film on a side surface of the first groove (step S520), and mainly etching the second coating film to form the hole pattern and the mask pattern (step S530). Hereinafter, the step S510 of partially etching the second coating film to form the first groove may be referred to as a partial etching step, and the step S530 of mainly etching the second coating film to form the hole pattern and the mask pattern may be referred to as a main etching step.

Firstly, as illustrated in FIG. 30, in the step S510 (partial etching step) of forming the first groove by partially etching the second coating film, the photoresist PR may be placed on the second coating film 830. The photoresist PR may be disposed so as to overlap a portion where the mask pattern MPT is to be formed, and may be disposed so as not to overlap a portion where the hole pattern HPT is to be formed.

In one or more other embodiments, a hard mask may be further disposed between the second coating film 830 and the photoresist PR. In this case, the hard mask may remain and form the third coating film 840 of the deposition mask 800 according to another embodiment described above with reference to FIG. 20. In still another embodiment, a hard mask may be used instead of the photoresist PR.

Next, a portion of the second coating film 830 may be etched by an etching device HD to form a first groove GRV1. For example, a portion of the second coating film 830 where the photoresist PR is not placed may be etched to form the first groove GRV1. The partial etching step may be performed by a dry etching process, and in the partial etching step, the second coating film 830 may be etched only to a certain depth out of its full depth.

Secondly, as illustrated in FIG. 31, in the step S520 of forming the passivation film on the side surface of the first groove, a passivation film PVX may be formed on the side surface of the first groove GRV1 and the side surface of the photoresist PR.

The passivation film PVX may contain a fluorocarbon (CₓF_{y})-based polymer. For example, the passivation film PVX may be formed using a fluorocarbon (CₓF_{y})-based source gas such as octafluorocyclobutane (C₄F₈) or octafluorocyclopentene (C₅F₈).

The passivation film PVX may prevent the second portion MPT2 of the mask pattern MPT and the photoresist PR from being etched during the main etching step.

Thirdly, as shown in FIGS. 32 and 33, in the step S530 (main etching step) of mainly etching the second coating film to form the hole pattern and the mask pattern, the second coating film 830 may be completely etched by the etching device HD to form the hole pattern HPT and the mask pattern MPT. For example, a portion of the second coating film 830 disposed under the first groove GRV1 may be etched to form a second groove GRV2, and a portion of the second coating film 830 disposed under the second groove GRV2 may be etched to form a third groove GRV3. The main etching step may be performed by a dry etching process, and in the main etching step, the second coating film 830 may be ultimately etched to its full depth.

For example, the second portion MPT2 of the mask pattern MPT may be formed on one side of the first groove GRV1 formed by the partial etching step, the second sub-portion MPT12 of the first portion MPT1 of the mask pattern MPT may be formed on one side of the second groove GRV2 formed by a first main etching step S530a, and the first sub-portion MPT11 of the first portion MPT1 of the mask pattern MPT may be formed on one side of the third groove GRV3 formed by a second main etching step S530b.

In the drawing, a case where the main etching step is performed twice is illustrated as an example. Without being limited thereto, however, the main etching step may be performed once or more than two twice, and in this case, the number of the grooves or the number of the sub-portions of the first portion MPT1 of the mask pattern MPT may vary. For example, when the main etching step is performed twice, the deposition mask according to another embodiment described with reference to FIG. 21 may be formed, and when the main etching step is performed once, the deposition mask according to one or more embodiments described with reference to FIG. 16 may be formed.

A portion of the first coating film 820 may be etched by over-etching in the main etching step. In this case, a fourth groove GRV4 may be formed in the first coating film 820.

In the method S1 of manufacturing the deposition mask according to the present embodiment, the etching device HD may generate plasma using an inductively coupled plasma (ICP) method. Through this method, the density of the plasma may be increased, and the energy of the charged particles may be relatively lowered, thereby increasing the isotropic characteristics.

In the method S1 of manufacturing the deposition mask according to the present embodiment, the etching device HD may apply different pressures, source powers (or RF powers), and bias powers within a chamber in the partial etching step and the main etching step.

For example, the pressure within the chamber in the partial etching step may be lower than the pressure within the chamber in the main etching step. The source power in the partial etching step may be less than the source power in the main etching step. The bias power in the partial etching step may be greater than the bias power in the main etching step. Accordingly, the side inclination angle of the second portion MPT2 of the mask pattern MPT may be formed to be smaller than the side inclination angle of the first portion MPT1.

In another example, even in the main etching step, the etching device HD may vary the pressure within the chamber, the source power (or RF power), and the bias power. For example, the pressure within the chamber in the first main etching step S530a may be lower than the pressure within the chamber in the second main etching step S530b. The source power in the first main etching step S530a may be lower than the source power in the second main etching step S530b. The bias power in the first main etching step S530a may be lower than the bias power in the second main etching step S530b. Accordingly, the side inclination angle of the second sub-portion MPT12 of the mask pattern MPT may be formed to be smaller than the side inclination angle of the first sub-portion MPT11.

According to the method S1 of manufacturing the deposition mask according to the present embodiment, the shapes of the mask pattern MPT and the hole pattern HPT can be controlled by controlling the pressure within the chamber, the source power, and the bias power of the etching device HD. Accordingly, it is possible to form the deposition mask 800 including the mask pattern MPT having a reverse-tapered shape.

Specifically, when the pressure within the chamber is increased, the number of collisions between ions and neutral particles may increase, so that the directionality of the ions may weaken, and thus the isotropy may increase. In addition, when the source power is increased, the plasma density may increase, so that the isotropy may increase due to relatively low energy of the charged particles. Besides, when the bias power is lowered, the energy of the charged particles may decrease, so that the isotropy may increase.

In the main etching step, a fluorine-based reaction gas may be additionally injected into the chamber by the etching device HD. For example, the fluorine-based gas may be sulfur hexafluoride (SF₆), tetrafluoromethane (CF₄), trifluoromethane (CHF₃), octafluorocyclobutane (C₄F₈), and/or nitrogen trifluoride (NF₃).

In concluding the detailed description, those skilled in the art will appreciate that many variations and modifications can be made to the embodiments without substantially departing from the principles and scope of the present disclosure. Therefore, the embodiments of the present disclosure are used in a generic and descriptive sense only and not for purposes of limitation.

What is claimed is:

1. A deposition mask comprising:
a mask substrate comprising a semiconductor wafer;
a first coating film on the mask substrate; and
a second coating film on the first coating film and comprising a hole pattern and a mask pattern that are alternately arranged,
wherein an upper width of the hole pattern is less than a lower width thereof.

2. The deposition mask of claim 1, wherein the first coating film comprises silicon oxide.

3. The deposition mask of claim 1, wherein the second coating film comprises silicon nitride.

4. The deposition mask of claim 3, wherein the second coating film comprises low stress nitride.

5. The deposition mask of claim 1, further comprising a mask opening penetrating at least a part of the mask substrate and at least a part of the first coating film,
wherein the mask opening communicates with the hole pattern.

6. The deposition mask of claim 5, wherein the mask substrate comprises a first surface and a second surface located opposite the first surface,
wherein the first coating film comprises a first upper coating film on the first surface, and a first lower coating film on the second surface,
wherein the second coating film comprises a second upper coating film on the first surface, and a second lower coating film on the second surface, and
wherein the mask opening penetrates the second lower coating film, the first lower coating film, the mask substrate, and the first upper coating film.

7. The deposition mask of claim 1, wherein the mask pattern comprises a first portion and a second portion on the first portion, and
wherein an upper width of the first portion is greater than a lower width of the first portion.

8. The deposition mask of claim 7, wherein a first angle between a bottom surface and a side surface of the first portion is different from a second angle between a bottom surface and a side surface of the second portion.

9. The deposition mask of claim 8, wherein the first angle is greater than the second angle.

10. The deposition mask of claim 7, wherein an angle between a bottom surface and a side surface of the first portion is an obtuse angle.

11. The deposition mask of claim 10, wherein the side surface of the first portion is an inclined surface that is inclined in an inward direction of the first portion as it goes from a top surface to a bottom surface thereof.

12. The deposition mask of claim 7, wherein an upper width of the second portion is greater than or equal to a lower width thereof.

13. The deposition mask of claim 12, wherein an angle between a bottom surface and a side surface of the second portion is a right angle or an obtuse angle.

14. The deposition mask of claim 13, wherein the side surface of the second portion is an inclined surface that is inclined in an inward direction of the second portion as it goes from a top surface to a bottom surface thereof.

15. The deposition mask of claim 7, wherein the first portion comprises a first sub-portion and a second sub-portion on the first sub-portion, and
wherein a third angle between a bottom surface and a side surface of the first sub-portion is different from a fourth angle between a bottom surface and a side surface of the second sub-portion.

16. The deposition mask of claim 1, further comprising an alignment mark on the mask substrate,
wherein the alignment mark is between the mask substrate and the first coating film or between the first coating film and the second coating film.

17. A method for manufacturing a deposition mask, the method comprising:
forming a first coating film on a mask substrate comprising a semiconductor wafer, and a second coating film on the first coating film;
forming a mask pattern and a hole pattern in the second coating film; and
forming a mask opening penetrating the mask substrate and the first coating film,
wherein the forming of the mask pattern and the hole pattern in the second coating film comprises:
partially etching the second coating film to form a first groove;
forming a passivation film on a side surface of the first groove; and
mainly etching the remaining second coating film under the first groove to form the hole pattern and the mask pattern.

18. The method of claim 17, wherein the second coating film comprises low stress nitride, and
wherein the second coating film is formed by a low pressure chemical vapor deposition (LPCVD) process.

19. The method of claim 17, wherein the passivation film comprises a fluorocarbon-based polymer.

20. An electronic device comprising:
a processor to provide input image data; and
a display device to display an image based on the input image data, wherein the display device is manufactured using the deposition mask of claim 1.
